(19) United States
(12) Patent Application Publication
(10) Pub. No.: US 2024/0311698 A1
(43) Pub. Date: Sep. 19, 2024

(54) MEASUREMENT METHOD AND APPARATUS FOR SEMICONDUCTOR FEATURES WITH INCREASED THROUGHPUT

(71) Applicant: Carl Zeiss SMT GmbH, Oberkochen (DE)

(72) Inventors: Alexander Freytag, Erfurt (DE); Oliver Malki, Aalen (DE); Johannes Persch, Etgert (DE); Thomas Korb, Schwaebisch Gmuend (DE); Jens Timo Neumann, Aalen (DE); Amir Avishai, Pleasanton, CA (US); Alex Buxbaum, San Ramon, CA (US); Eugen Foca, Ellwangen (DE); Dmitry Klochkov, Schwaebisch Gmuend (DE)

(21) Appl. No.: 18/673,373

(22) Filed: May 24, 2024

Related U.S. Application Data
(63) Continuation of application No. PCT/EP2022/082590, filed on Nov. 21, 2022.
Application No. PCT/EP2022/082590 is a continuation-in-part of application No. 17/701,054, filed on Mar. 22, 2022.
(60) Provisional application No. 63/291,569, filed on Dec. 20, 2021.

(51) Int. Cl. G06N 20/00; G01N 23/2251

(52) U.S. Cl. CPC G06N 20/00; G01N 23/2251; G01N 2223/401; G01N 2223/6116

(57) ABSTRACT

A system and a method for measuring of parameter values of semiconductor objects within wafers with increased throughput include using a modified machine learning algorithm to extract measurement results from instances of semiconductor objects. A training method for training the modified machine learning algorithm includes reducing a user interaction. The method can be more flexible and robust and can involve less user interaction than conventional methods. The system and method can be used for quantitative metrology of integrated circuits within semiconductor wafers.

### CROSS-REFERENCE TO RELATED APPLICATION

The present application is a continuation of, and claims benefit under 35 USC 120 to, International Application No. PCT/EP2022/082590, filed Nov. 21, 2022. PCT/EP2022/082590 is a continuation-in part of, and claims benefit under 35 USC 120 to, U.S. application Ser. No. 17/701,054, filed Mar. 22, 2022, which claims benefit under 35 USC 119 of U.S. Application No. 63/291,569, filed Dec. 20, 2021. The entire disclosures of these applications are incorporated by reference herein.

### FIELD

The present disclosure relates to a three-dimensional circuit pattern measurement method of semiconductor objects within a semiconductor wafer and related technologies, such as a method, computer program product and a corresponding semiconductor inspection device for measuring parameters of semiconductor objects such as HAR structures with increased throughput. With the semiconductor inspection device configured for performing the method, parameter values of repetitive semiconductor objects can be measured by a metrology method utilizing machine learning. The method, computer program product and semiconductor inspection device can be utilized for quantitative metrology, defect detection, process monitoring, or defect review of integrated circuits within semiconductor wafers.

### BACKGROUND

Semiconductor structures are amongst the finest man-made structures. Semiconductor manufacturing generally involves precise manipulation, e.g., lithography or etching, of materials such as silicon or oxide at very fine scales in the range of nm. A wafer made of a thin slice of silicon serves as the substrate for microelectronic devices containing semiconductor structures built in and upon the wafer. The semiconductor structures are typically constructed layer by layer using repeated processing steps that involve repeated chemical, mechanical, thermal and optical processes. Dimensions, shapes and placements of the semiconductor structures and patters are often subject to several influences. During the manufacturing of 3D-memory devices, the processes include etching and deposition. Other process steps such as the lithography exposure or implantation also can have an impact on the properties of the elements of the integrated circuits. Therefore, fabricated semiconductor structures can suffer from rare and different imperfections. Devices for quantitative metrology, defect-detection or defect review look for these imperfections. These devices are typically used during wafer fabrication. As this fabrication process is complicated and highly non-linear, optimization of production process parameters can be difficult. As a remedy, an iteration scheme called process window qualification (PWQ) can be applied. Generally, in each iteration a test wafer is manufactured based on the currently best process parameters, with different dies of the wafer being exposed to different manufacturing conditions. By detecting and analyzing the test structures with devices for quantitative metrology and defect-detection, the best manufacturing process parameters can be selected. In this way, production process parameters can be tweaked towards optimality. Afterwards, a highly accurate quality control process and device for the metrology semiconductor structures in wafers is usually involved.

Fabricated semiconductor structures are generally based on prior knowledge. The semiconductor structures are manufactured from a sequence of layers being parallel to a substrate. For example, in a logic type sample, metal lines run parallel in metal layers or HAR (high aspect ratio) structures and metal vias run perpendicular to the metal layers. The angle between metal lines in different layers is either 0° or 90°. On the other hand, for VNAND type structures it is known that their cross-sections are circular on average. Furthermore, a semiconductor wafer has a diameter of 300 mm and consist of a plurality of several sites, so called dies, each including at least one integrated circuit pattern such as for example for a memory chip or for a processor chip. During fabrication, semiconductor wafers typically run through about 1000 process steps, and within the semiconductor wafer, about 100 and more parallel layers are often formed, including the transistor layers, the layers of the middle of the line, and the interconnect layers and, in memory devices, a plurality of 3D arrays of memory cells.

The aspect ratio and the number of layers of integrated circuits constantly increases and the structures are growing into 3rd (vertical) dimension. The current height of the memory stacks exceeds a dozen of microns. In contrast, the features size is becoming smaller. The minimum feature size or critical dimension is below 10 nm, for example 7 nm or 5 nm, and is approaching feature sizes below 3 nm in near future. While the complexity and dimensions of the semiconductor structures are growing into the third dimension, the lateral dimensions of integrated semiconductor structures are becoming smaller. Therefore, measuring the shape, dimensions and orientation of the features and patterns in 3D and their overlay with high precision becomes challenging. The lateral measurement resolution of charged particle systems is typically limited by the sampling raster of individual image points or dwell times per pixel on the sample, and the charged particle beam diameter. The sampling raster resolution can be set within the imaging system and can be adapted to the charged particle beam diameter on the sample. The typical raster resolution is 2 nm or below, but the raster resolution limit can be reduced with no physical limitation. The charged particle beam diameter has a limited dimension, which depends on the charged particle beam operation conditions and lens. The beam resolution is limited by approximately half of the beam diameter. The lateral resolution can be below 2 nm, for example even below 1 nm.

A common way to generate 3D tomographic data from semiconductor samples on nm scale is the so-called slice and image approach obtained for example by a dual beam device. A slice- and image approach is described in WO 2020/244795 A1. According to the method of the WO 2020/244795 A1, a 3D volume inspection is obtained at an inspection sample extracted from a semiconductor wafer. In another example, the slice and image method is applied under a slanted angle into the surface of a semiconductor wafer, as described in WO 2021/180600 A1. According this method, a 3D volume image of an inspection volume is obtained by slicing and imaging a plurality of cross-section surfaces within the inspection volume. For a precise measurement, a large number N of cross-section surfaces in the inspection volume is generated, with the number N exceeding 100 or even more image slices. For example, in a volume with a lateral dimension of 5 μm and a slicing distance of 5 nm, 1000 slices are milled and imaged. With a typical sample of a plurality of HAR structures with a pitch of for example 70 nm, about 5000 HAR structures are in one field of view, and a total sum of more than five million cross sections of HAR structures is generated. Several ideas have been proposed to reduce the huge computational effort of extracting the desired measurement results. WO 2021/180600 A1 illustrates some methods which utilize a reduced number of images slices. In an example, the method applies a priori information.

A task of semiconductor inspection is to determine a set of specific parameters of semiconductor objects such as high aspect ratio (HAR)-structures inside the inspection volume. Such parameters are for example a dimension, area, a shape, or other measurement parameters. Typically, the measurement task involves several computational steps like object detection, feature extraction, and any kind of a metrology operation, for example a computation of a distance, a radius or an area from the extracted features. Of these many steps, in general, each involves a high computational effort.

Generally, semiconductors include many repetitive three-dimensional structures. During the manufacturing process or a process development, some selected physical or geometrical parameters of a representative plurality of the three-dimensional structures are usually measured with high accuracy and high throughput. For monitoring the manufacturing, an inspection volume is defined, which includes the representative plurality the three-dimensional structures. This inspection volume is then analyzed for example by a slice and image approach, leading to a 3D volume image of the inspection volume with high resolution.

The plurality of repetitive three-dimensional structures inside an inspection volume can exceed several 100 or even several thousand individual structures. Thereby, a huge number of cross section images is generated, for example at least 100 three-dimensional structures are investigated by 100 cross section image slices, thus the number of measurements to be performed may easily reach 10000 or more.

Machine learning is a field of artificial intelligence. Machine learning algorithms generally build a machine learning model based on training data consisting of a large number of training samples. After training, the algorithm is able to generalize the knowledge gained from the training data to new previously unencountered samples, thereby making predictions for new data. There are many machine learning algorithms, e.g., linear regression k-means or neural networks. For example, deep learning is a class of machine learning that uses artificial neural networks with numerous hidden layers between the input layer and the output layer. Due to this extensive internal structure the networks are able to progressively extract higher-level features from the raw input data. Each level learns to transform its input data into a slightly more abstract and composite representation, thus deriving low and high level knowledge from the training data. The hidden layers can have differing sizes and tasks such as convolutional or pooling layers. Up to now, machine learning is frequently applied to defect detection or classification during semiconductor inspection. For example, during defect detection, a machine learning algorithm is trained to flag defects and to classify defects in discrete defect classes. The training data involved typically involves images of prior identified defects with a few classification labels. The steps of object detection or feature extraction usually involve a classical pattern recognition algorithm or a machine learning algorithm.

U.S. Pat. No. 6,054,710 shows an example of an application of machine learning techniques to a measurement task. Here, a cross section of a semiconductor line shall be estimated. The semiconductor lines at this time had a topography, which reduced the resolution of the top-down image generated by an electron microscope. The effect of the edge slope on the top-down image is considered by a machine learning network, trained by edge slope data obtained with an AFM. In actual applications and recent desired properties, however, milled or polished 2D cross sections of semiconductor wafers are to be investigated, absent of any edge slopes, and electron microscope images do not suffer from topography effects. US 2020/0258212 A1 proposes a new example of the application of machine learning to the measurement of semiconductor objects of interest, with a special focus on edge roughness. While US 2020/0258212 A1 discloses the general concept of application of machine learning to measurement tasks, it may not be sufficiently developed for practical implementation with less training effort.

Typical machine learning algorithms involve an intensive training, including intensive interaction by an operator or user. The user annotates a huge set of images with annotation tags for successfully training a machine learning algorithm. This can be unfeasible due to the large annotation effort. In order to manage the labeling effort for the annotation of large datasets, active learning has been proposed. Such an active learning system for the classification of anomalies has been disclosed in the U.S. Pat. No. 11,138,507 B2, where a plurality of defects in a specimen are associated with a predefined set of classes via a trained classifier. To obtain new training data, a sample of low likelihood is selected from each class and presented together with samples of high likelihood of the same class to obtain a binary decision from the user. However, again an elaborative user interaction is involved.

### SUMMARY

The disclosure seeks to provide an efficient method to perform measuring tasks at semiconductor objects of interest. The disclosure also seeks to reduce the number of steps of a measurement task and reduce the high computational effort. The disclosure further seeks to improve the methods provided in US 2020/0258212 A1. In addition, the disclosure seeks to improve certain known methods for measuring HAR channels. The disclosure also seeks to reduce the amount of user interaction for implementing a measurement task. Generally, the disclosure seeks to provide a wafer inspection method for the measurement of semiconductor structures in inspection volumes with high throughput and high accuracy. The disclosure further seeks to provide a generalized wafer inspection method for the measurement of semiconductor structures in inspection volumes, which can quickly be adapted to changes of the measurement tasks, the measurement system, or to changes of the semiconductor object of interest. In addition, the disclosure seeks to provide a fast, robust and reliable measurement method of a set of parameters describing semiconductor structures in an inspection volume with high precision and with reduced measurement artefacts.

According to an aspect of the disclosure, a contiguous machine learning algorithm is directly applied to a measuring task. However, to perform a measurement with one step including a contiguous machine learning algorithm, a large amount of annotated training image data is involved. The annotated training image data is involved to cover the desired measurement value range of the selected physical or geometrical parameters.

According to a first embodiment of the disclosure, a segmentation and annotation method is provided to generate training image data for a measuring task with reduced used interaction. The method according to the first embodiment includes a computer assisted method to generate the training data for a measuring algorithm utilizing machine learning. With the annotated training image data, a training of the machine learning algorithms for the measuring task can be achieved or modified and a measurement result can be obtained which is robust against defects or deviations. Further, the training data can further include identifiers to defect classes according to the certain error types. The method of generating training data according to the first embodiment relies on prior information. By using a priori information, the effort and especially any user interaction during training is reduced to a minimum.

A first part of the prior information can be given by the selection of an appropriate parametrized description of the semiconductor object of interest. A parametrized description of the semiconductor object of interest can include geometrical shapes such as a circle, a ring, an ellipse, a polygon, or expansion coefficients of a series expansion, or the like. For example, a parametrized description of an HAR channel cross section includes a set of concentric circles. The parametric descriptions can be displayed as an overlay over cross section images, obtained by a charged particle beam system. The user interaction can then be limited to a change of few parameters of the parametric descriptions, for example a center position, a radius of a ring or to change the position of a point in a polygon instead of pixelwise annotation. The parametric descriptions can be selected according to CAD data. The parametric descriptions can be selected from a library including typical user templates of parametric descriptions. In another example, the parametrized description can entirely be derived from CAD data of the semiconductor object of interest.

A second part of the prior information can be given by parameters of the charged particle imaging system (such as dwell time, pixel size, landing energy, material contrasts, charge compensation measures).

During a segmentation step in certain known methods, pixels or voxels inside a 2D or 3D image are assigned to a selected structure. Training of a machine learning segmentation involves to provide pixel/voxel annotations for many pixels or voxels/in many images. This standard method of segmentation by user interaction and segmenting pixel by pixel is very time consuming-especially if one has precision properties like in semiconductor industry where sometimes structures are confined within only few 3-4 pixels.

In a first example according to the first embodiment of the disclosure, the generation of training image data is achieved by using a parametrized description of the semiconductor object of interest and the training image data is generated to cover the expected parameter value range to be measured. An example of elements of a parametrized geometrical description are the rings or shells of high-aspect-ratio (HAR) structures or HAR channels. A parameter is for example given by a radius of a cricle or ring. A parameter value range is then the expected deviation of a radius from a design value, for example with a radius value between 5 nm and 6 nm. For example, edges or boundaries of HAR channels are used as input to a contour engine, which derives a measurement results as a continuous parameter value. The measurement result is used as annotation label of the identified semiconductor object of interest, by which the training image is annotated. According to the first example of the first embodiment, a user provides prior information by selection of a parametrized description, for example the number of circles or rings, the radii of the circles, the distance between centers of HAR structures, or similar. The parametrized description is then displayed over the training cross section image segments, either by manual placement of elements of the parametrized description or by automated methods, such as image processing. For example, a user selects centers, number of circles, approximate radii of the circles, or other parameters of the selected parametrized description. A processing algorithm can assist the user for a semi-automatic placement and adjustment of elements of the parametrized description, thereby readjusting the centers, radii, and the like. A processing algorithm can further assist by automatically determining parameter values by for example image processing, thereby readjusting the elements to represent the measurement parameter values. In an example, an automated determination the initial annotation values includes the step of application of a physical-inspired forward simulation model to a parametric description of the semiconductor object of interest. With the physical simulation model, an expected image of a semiconductor object of interest obtained with a charged particle beam imaging device is generated by simulation. In an optimization step, the unknown parameter values of the parametric description of a semiconductor object of interest are obtained.

At each step, the elements of the parametric description such as the circles or rings can be superposed over a training cross section image segment, and a user can modify the parameter values by known methods of computer-graphics for geometrical elements. The last step of the segmentation and annotation includes the step of annotating each training cross section image segment with the parameter values of the parametrized description of the detected instances of the semiconductor object of interest within each training cross section image segment. The segmentation result can be further used for a mapping of the pixels of the 2D training cross section image segment and a pixelated segmentation is achieved. The pixelated segmentation can further be utilized to for example combine a measuring machine learning algorithm with a defect detection and classification algorithm.

In a plurality of representative training cross section image segments, typically a limited range of measurement results of the parameter value are determined. With a set of training cross section image segments, thus training data for a limited parameter value range are generated. A machine learning algorithm or regressor according to the second embodiment, trained with the training data is therefore capable of detecting and determining the continuous quantitative measures of the parameter of semiconductor structures of interest in a new image. The regressor of the machine learning algorithm generates directly the measurement values of a plurality of HAR channels from a new 2D image. For a metrology application, a quality measure for a machine learning algorithm can for example be defined by the deviation of an actually measured value from a training parameter value. The quality measure can therefore be improved by utilizing a dense coverage of the predetermined parameter value range.

According to a second example of the method of the first embodiment, a coverage of the predetermined parameter value range is automatically improved by utilizing first segmented and annotated training cross section image segments obtained by user interaction. Further annotated training cross section image segments with additional parameter values within the predetermined parameter value range can for example by generated by image processing. Example of suitable image processing includes at least one of a variation of a scale, a change of a shape, an interpolation, a morphologic operation, or a pattern substitution within a training cross section image segment. Further training cross section image segment can be generated by physical simulation of the process of obtaining cross section image segments based on the selected parametrized description of the semiconductor object of interest and imaging parameters of the charged particle beam system.

In a third example of the method according to the first embodiment, the user interaction is even further reduced. The method for generating training data for training of a machine learning algorithm for performing a quantitative measurement can generally be improved by a-priori knowledge. During measurement tasks of semiconductor structures, generally two steps are known a priori.

First, the imaging properties of the imaging process by the imaging instrument are known. Typically, a charged particle beam system utilizing electrons or ions such as Helium ions as primary charged particles is used. Generally, imaging parameters such as dwell time, pixel size, landing energy, material contrasts, or charge compensation measures been taken are known. The imaging contrast depends on a selected contrast method and know material contrast. Resolution is usually depending on the pixel resolution and the point spread function of the charged particle beam system. Imaging noise is determined by the imaging conditions, for example the scanning speed or dwell time during imaging.

Second, the target form of the semiconductor structure is generally known from CAD information and information about the fabrication process steps, involved during fabrication.

Further, the list of involved materials is limited, and the material contrasts are known or can be determined with high precision.

According to the third example of the first embodiment, the method of generating training data applies a physical simulation of the imaging process. From the CAD information, a parametrized description of the repetitive semiconductor object of interest is selected and a plurality of semiconductor objects of interest according to the parametrized description is generated. In the plurality of semiconductor objects of interest, the parameter values are varied within a predetermined parameter value range. Thereby, a large amount of training cross section image segments, covering the predetermined parameter value range, can automatically be generated with minimum user interaction. The physical simulation employs a simulation of the imaging process for a given charged particle imaging system, for which the imaging parameters can be previously determined and stored in a memory of the charged particle imaging system.

The general advantage of the segmentation and annotation method according to the first embodiment is a large reduction of the annotation effort by reducing the user interaction to a minimum. The system configured to perform the methods according to the first embodiment is thus capable of quickly adapting to new measurement tasks of new semiconductor objects of interest or, semiconductor objects of interest of different size or scale after for example a shrink of the integrated semiconductor structure. In an example, a set of training data is based on existing annotated training images, for example covering a narrow range of measurement values, or a different range or measurement values. Further annotated training images are generated by image processing of the annotated training images to cover a desired range of measurement values. This is for example useful when a shrink is applied to the semiconductor structures, or when a magnification of the imaging process is changed.

The segmentation and annotation method according to the first embodiment offers the further advantage to quickly adopt the parametrized description to a new semiconductor object or a deviation of the shapes of the semiconductor object of interest by introducing new, additional parameters. For example, if the HAR channels show a frequent deviation from a circular shape, and additional parameter of an ellipticity can be introduced in an existing set of training data. The introduction can for example be performed in refinements step or by automatic generation of additional training cross section image segments covering parameter value range of the newly introduced parameter, for example an ellipticity. For example, if a material or material composition of a semiconductor object of interest is changed, the training data can automatically be adapted to the new material contrast corresponding to the new material or material composition.

In an example, the generation of training image data is not completed after an initial training. Typically, not all effects or defects during manufacturing are foreseen in an initial training, and the machine learning algorithm has frequently been modified during the monitoring of a manufacturing process. According to an aspect of the first embodiment, a method is provided to further modify the training image data for a measuring task with reduced used interaction.

In a first example, modified annotated training image data are provided to cover unexpected effects during the manufacturing. During manufacturing, certain errors types can further be detected, for example regular and repetitive errors or defects from for example a contamination of a lithography mask used during the manufacturing. Other defects can be random, for example a sporadic contamination during a manufacturing process step. Additional modified annotated training image data are provided for example by image processing, including for example an additional noise level, an addition of a particle defect, or a deviation in image contrast.

In a second example, modified annotated training image data are provided to cover unexpected effects during the imaging process. The initial annotated training image data initially covers the effects of the image generation process, such as a magnification, a noise level, a material contrast, a convolution kernel such as a point spread function. Imaging effects can for example be curtaining effects during a slice- and image process, leading to an unexpected topography contrast in addition to a material contrast of the SEM images. Such contrasts from curtaining can be considered in modified annotated training image data. Other effects are charging effects. Local sample charging has an influence on the local secondary electron yield and thus can change a material contrast and a primary particle beam focus position and thus generate locally distorted images or locally changed image contrast. Such images with locally changed image contrast and local distortion can be considered in modified annotated training image data. According to the method, initial or modified annotated training images can be generated automatically according to the expected imaging parameter value range of the measuring task. With such additional modified annotated training data, an inspection or measurement task using machine learning algorithm can be more robust.

According to a further aspect, an improved method of annotating training data is provided. The method comprises receiving a set of training cross section image segments of a semiconductor object of interest and selecting a parametrized description of the semiconductor object of interest. According to the method, a parameter value of a parameter of the parametrized description is adjusted to each detected instance of the semiconductor object of interest. Each detected instance of the semiconductor object of interest in the set of training cross section image segments is annotated with the adjusted parameter value. The parametrized description with the adjusted parameter value can be displayed to a user via a user graphical user interface or display.

According to a further aspect, a method of generating training data for a machine learning algorithm for image segmentation is provided. The method comprises receiving a set of training cross section images of the semiconductor object of interest and selecting a parametrized description of the semiconductor object of interest. The method comprises adjusting a parameter value of the parameter of the parametrized description to each detected instance of the semiconductor object of interest in the set of training cross section images and automatically annotating each image pixel with a pixel annotation value according to the adjusted parameter value of the parameter of the parametrized description.

According to a second embodiment of the disclosure, a method of measuring at least a parameter value of a plurality of semiconductor objects of interest by a one, single step or contiguous machine learning algorithm is provided. As a result, the method of measuring at least a parameter value of a plurality of semiconductor objects of interest extracts a list of parameter values of a parametric description of the plurality of semiconductor objects within a 2D image of a region of interest within a wafer. In an example, a set of measurement results is generated for each cross-section image of each HAR structure inside an inspection volume. The set of measurement results according to the parametric description can include diameters, center positions offsets, areas, distances, ellipticities, or other general geometrical properties. The set of parameters can further include presumed material compositions or other physical properties of the manufactured semiconductor devices, or the number of instances of the repetitive three-dimensional structures within the region of interest.

According to the second embodiment, machine learning methods (for example a deep neural network) are utilized to accomplish a metrology or measurement task, providing a continuous measurement result. Such a metrology or measurement task by machine learning involves a huge set of training data, which cover the range of expected measurement values. But instead of annotating with discrete and distinguished classes, each training image is annotated with a list of corresponding measurement results of at least one semiconductor structure of interest within the training image. The measurement method according to the second embodiment is therefore configured for a training with a set of annotated training images. With the method of generating or completing of training images according to the first embodiment, the contiguous machine learning algorithm can be trained with less user interaction and lower effort, and thus can be modified or adapted to new or changing measurement tasks. The second embodiment thus provides a fast, robust and adaptive measurement value extractor.

According to an aspect of the method according to the second embodiment, the method is further configured for generating modified annotated training data during a monitoring task and configured for an additional training with the modified annotated training images. The initial annotated training images initially cover an expected range of parameter values. The modified annotated training images can cover an extension to the parameter value range. In an example, a method is given to automatically generate initial or modified annotated training images inside ranges of parameters values to be measured by the measuring task.

The method of the second embodiment is configured for a minimum user interaction during a monitoring task. The measurement method according to the second embodiment is utilizing one contiguous machine learning algorithm for the measurement of parameter values according to a parametric description. The measurement method utilizing the parametric description offers the advantage of being highly robust against imaging variations. The measurement method utilizing a machine learning algorithm can operate at high noise levels, where classical measurement methods fail. The measurement method according to the second embodiment can be implemented to perform very fast.

Furthermore, since no complicated physical simulation models of classical metrology methods are implemented, the method can easily be adapted to a variety of semiconductor objects of interest, including changes of a semiconductor object of interest, or changes of the imaging condition of the charged particle imaging system.

According to an example, the measurement method is including the step of obtaining a series of J cross-section image slices of a semiconductor wafer at an inspection position. The series of J cross-section image slices includes at least a first cross-section image slice at a first angle and a second cross-section image slice at a second angle through the inspection volume. The first and second angle can be equal or different. The cross-section image slices are generated and obtained by a slice- and imaging method, using a dual beam device including a FIB column for milling and a charged particle imaging system for imaging.

According to an example, the method is applied to HAR channels of a memory device, and a plurality of HAR channel cross section images are generated by the slice- and imaging method. The measurement method is trained according to a parametric description of HAR channels, including a set of elements including circles or rings. The measurement method provides as measurement result for example the parameter values such as a numerical value of a radius, a diameter, an ellipticity, or a deviation from an average center position of the set of circles or rings.

In an example, a measurement method according to the second method is further including the steps of determining an inspection position of an inspection volume in the wafer and adjusting the wafer with the inspection position at the cross-section of a dual beam device. The inspection positions can be obtained for an inspection control file or list generated and provided from a further inspection tool or from a list of positions of process control monitors.

A system configured for implementing the measurement method according to the second embodiment is described in the third embodiment. The system according to the third embodiment is including a user interface, configured to receive user information about the measurement task, for example CAD information of the inspection volume or expected ranges of the desired measurement value ranges. The system is configured to combine the user information with process information of the image generation process, for example selected imaging parameters of the dual beam system. The user interface is connected to a processing engine, which is configured to combined user and process information, and to generate annotated training images with reduced user interaction. The process information of the image generation process can for example include a library of the effects during the image generation. According to an example, the processing engine is configured to generate annotated training images by physical simulation or image processing.

In an example, the processing engine is configured to generate training images by physical simulation, based on CAD-data of the three-dimensional structures. The user interface is thus configured to receive, display, select and store CAD-data in a memory. The processing engine is configured to consider information of the imaging process with for example a dual beam device. The user interface is thus configured to receive, display, and select imaging parameters of the dual beam device. The imaging parameters can for example be selected by a user according to a desired speed or accuracy of the measurement task. The processing engine is further configured to consider material contrast, for example by a predetermined and stored library data of secondary electron yields for the specific material composition of semiconductor objects of interest. The processing engine is further configured to consider an imaging noise according to a secondary electron collection efficiency and a dwell time according to the imaging parameters and the material composition of semiconductor objects of interest.

In an example of the third embodiment, a system for performing a measurement task is configured for measuring parameter values of semiconductor objects in an inspection volume with high throughput. The system includes a FIB column arranged and configured for milling a series of cross-sections surfaces at an inspection site into the surface of wafer and a charged particle imaging microscope arranged and configured for acquiring digital images of the series of cross-sections surfaces. The system includes a stage configured for holding and positioning the inspection site of a wafer and a control unit configured for controlling the operation of milling and imaging the series of cross-sections surfaces. The system further includes a computing or processing unit configured for measuring a plurality of parameter values inside of an inspection volume of a semiconductor wafer according to a method of the second embodiment. The computing or processing unit includes a memory with software installed and a processing unit configured for operating and processing the digital images of the series of cross-sections surfaces according to the software code installed. The computing or processing unit is in communication with an interface for receiving commands and a control unit for receiving the digital image data. The computing or processing unit is in communication with an interface or control unit of the dual beam device for exchanging and providing control commands such as milling angles GF and y-positions of cross-sections through the inspection volume.

The system for performing an measurement task of semiconductor objects includes the following features: an imaging device adapted to provide an imaging dataset of a wafer, a graphical user interface configured to present data to the user and obtain input data from the user, one or more processing devices, one or more machine-readable hardware storage devices including instructions that are executable by one or more processing devices to perform operations including one of the methods disclosed herein. The disclosure also relates to one or more machine-readable hardware storage devices including instructions that are executable by one or more processing devices to perform operations including one of the methods according to the first or second embodiments.

According to the embodiments of the disclosure, it is therefore possible to quickly adapt a wafer inspection method for the measurement of semiconductor objects of interest to changing conditions, for example changes of the measurement tasks, changes of the charged particle beam imaging system, or to changes of the semiconductor object of interest itself. Therefore, a generalized wafer inspection method with high flexibility is provided.

According to an aspect of the disclosure, a system and a method for volume inspection of semiconductor wafers with increased throughput is provided. The system and method is configured for a milling and imaging of appropriate cross-sections surfaces in an inspection volume and determining measurement parameters of the 3D objects from the cross-section surface images. The disclosure provides a device and a method for 3D inspection of an inspection volume in a wafer and for the measuring of parameter values of semiconductor objects inside of the inspection volume with high throughput, high accuracy and reduced damage to the wafer. The method and device is utilized for quantitative metrology, but can also be used for defect detection, process monitoring, defect review, and inspection of integrated circuits within semiconductor wafers.

While the examples and embodiments of the disclosure are described at the examples of semiconductor wafers, it is understood that the disclosure is not limited to semiconductor wafers, but can for example also be applied to reticles or masks for semiconductor fabrication.

The disclosure described by examples and embodiments is not limited to the embodiments and examples but can be implemented by those skilled in the art by various combinations or modifications thereof.

### BRIEF DESCRIPTION OF THE DRAWINGS

The present disclosure will be even more fully understood with reference to the following drawings:

FIG. 1 shows an illustration of a wafer inspection or metrology system for 3D volume inspection with a dual beam device;

FIG. 2 is an illustration of the slice- and image method of a volume inspection in a wafer;

FIG. 3 illustrates an example of a cross section image, obtained by the slice- and image method;

FIG. 4 is a simplified illustration of method steps;

FIG. 5 illustrates an example of a training method;

FIG. 6 illustrates a first example of a user interface display configured for a training method;

FIG. 7 illustrates a second example of a user interface display configured for a training method;

FIG. 8 illustrates a third example of a user interface display configured for a training method;

FIG. 9 illustrates an example of a physical simulation of training images;

FIG. 10 illustrates an example of an enhancement of training data;

FIGS. 11A-11G Illustrate of the process steps of an annotation process;

FIG. 12 illustrates a method for measuring parameter values;

FIG. 13 illustrates a machine learning algorithm for a measuring task

FIGS. 14A-14B illustrate two examples of an analysis and display of measurement results

FIG. 15 illustrates a system for performing a measurement task;

FIGS. 16A-16B illustrate an example of a parametric description describing an abstract relation; and

FIGS. 17A-17B illustrate an example of a measurement of a parameter value of an abstract description.

### DETAILED DESCRIPTION

Throughout the figures and the description, same reference numbers are used to describe same features or components. The coordinate system is selected that the wafer surface 55 coincides with the XY-plane.

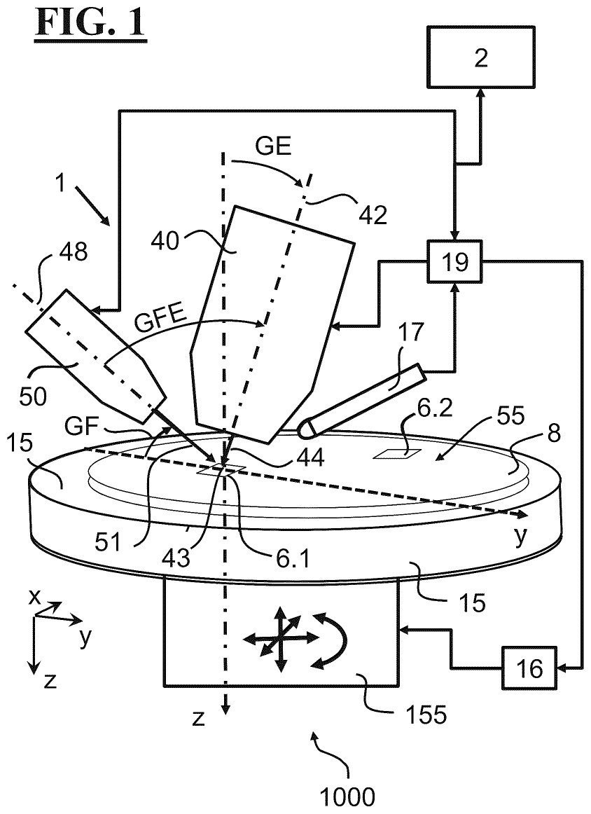

Recently, for the investigation of 3D inspection volumes in semiconductor wafers, a slice and imaging method has been proposed, which is applicable to inspection volumes inside a wafer. Thereby, a 3D volume image is generated at an inspection volume inside a wafer in the so called “wedge-cut” approach or wedge-cut geometry, without the need of a removal of a sample from the wafer. The slice and image method is applied to an inspection volume with dimensions of few μm, for example with a lateral extension of 5 μm to 10 μm in wafers with diameters of 200 mm or 300 mm. The lateral extension can also be larger and reach up to few 10ths of micrometers. A V-shaped groove or edge is milled in the top surface of an integrated semiconductor wafer to make accessible a cross-section surface at an angle to the top surface. 3D volume images of inspection volumes are acquired at a limited number of measurement sites, for example representative sites of dies, for example at process control monitors (PCM), or at sites identified by other inspection tools. The slice and image method will destroy the wafer only locally, and other dies may still be used, or the wafer may still be used for further processing. The methods and inspection systems according to the 3D Volume image generation are described in WO 2021/180600 A1, which is fully incorporated herein by reference. An example of a wafer inspection system 1000 for 3D volume inspection is illustrated in FIG. 1. The wafer inspection system 1000 is configured for a slice and imaging method under a wedge cut geometry with a dual beam device 1. For a wafer 8, several measurement sites, including measurement sites 6.1 and 6.2, are defined in a location map or inspection list generated from an inspection tool or from design information. The wafer 8 is placed on a wafer support table 15. The wafer support table 15 is mounted on a stage 155 with actuators and position control. Actuators and devices for precision control for a wafer stage such as Laser interferometers are known in the art. A control unit 16 configured to control the wafer stage 155 and to adjust a measurement site 6.1 of the wafer 8 at the intersection point 43 of the dual-beam device 1. The dual beam device 1 is including a FIB column 50 with a FIB optical axis 48 and a charged particle beam (CPB) imaging system 40 with optical axis 42. At the intersection point 43 of both optical axes of FIB and CPB imaging system, the wafer surface is arranged at a slant angle GF to the FIB axis 48. FIB axis 48 and CPB imaging system axis 42 include an angle GFE, and the CPB imaging system axis forms an angle GE with normal to the wafer surface 55. In the coordinate system of FIG. 1, the normal to the wafer surface 55 is given by the z-axis. The focused ion beam (FIB) 51 is generated by the FIB-column 50 and is impinging under angle GF on the surface 55 of the wafer 8. Slanted cross-section surfaces are milled into the wafer by ion beam milling at the inspection site 6.1 under approximately the slant angle GF. In the example of FIG. 1, the slant angle GF is approximately 30°. The actual slant angle of the slanted cross-section surface can deviate from the slant angle GF by up to 1° to 4° due to the beam divergency of the focused ion beam, for example a Gallium-Ion beam. With the charged particle beam imaging system 40, inclined under angle GE to the wafer normal, images of the milled surfaces are acquired. In the example of FIG. 1, the angle GE is about 15°. However, other arrangements are possible as well, for example with GE=GF, such that the CPB imaging system axis 42 is perpendicular to the FIB axis 48, or GE=0°, such that the CPB imaging system axis 42 is perpendicular to the wafer surface 55.

During imaging, a beam of charged particles 44 is scanned by a scanning unit of the charged particle beam imaging system 40 along a scan path over a cross-section surface of the wafer at measurement site 6.1, and secondary particles as well as scattered particles are generated. Particle detector 17 collects at least some of the secondary particles and scattered particles and communicates the particle count with a control unit 19. Other detectors for other kinds of interaction products may be present as well. Control unit 19 is in control of the charged particle beam imaging column 40, of FIB column 50 and connected to a control unit 16 to control the position of the wafer mounted on the wafer support table via the wafer stage 155. Control unit 19 communicates with operation control unit 2, which triggers placement and alignment for example of measurement site 6.1 of the wafer 8 at the intersection point 43 via wafer stage movement and triggers repeatedly operations of FIB milling, image acquisition and stage movements.

Each new intersection surface is milled by the FIB beam 51, and imaged by the charged particle imaging beam 44, which is for example scanning electron beam or a Helium-Ion-beam of a Helium ion microscope (HIM). In an example, the dual beam system includes a first focused ion beam system 50 arranged at a first angle GF1 and a second focused ion column arranged at the second angle GF2, and the wafer is rotated between milling at the first angle GF1 and the second angle GF2, while imaging is performed by the imaging charged particle beam column 40, which is for example arranged perpendicular to the wafer surface.

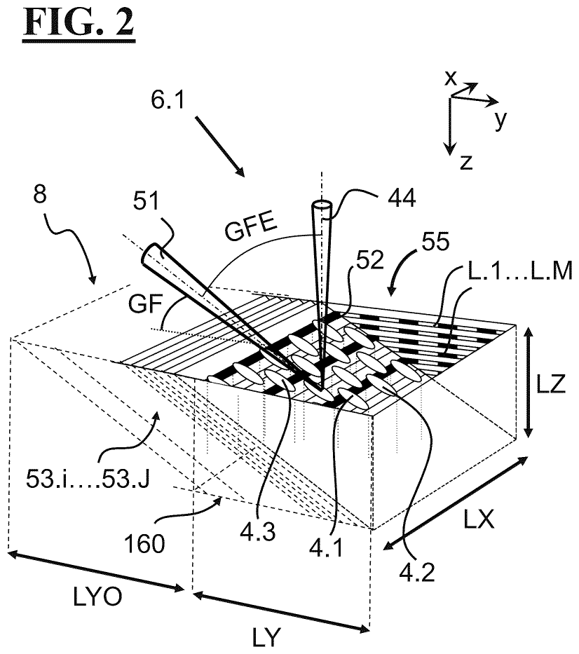

FIG. 2 illustrates the wedge cut geometry at the example of a 3D-memory stack. FIG. 2 illustrates the situation, when the surface 52 is the new cross-section surface which was milled last by FIB 51. The cross-section surface 52 is scanned for example by SEM beam 44, which is in the example of FIG. 2 arranged at normal incidence to the wafer surface 55, and a high-resolution cross-section image slice is generated. The cross-section surfaces 53.1 . . . 53.N are subsequently milled with a FIB beam 51 at an angle GF of approximately 30° to the wafer surface 9, but other angles GF, for example between GF=20° and GF=60° are possible as well. The cross-section image slice includes first cross-section image features, formed by intersections with high aspect ratio (HAR) structures or vias (for example first cross-section image features of HAR-structures 4.1, 4.2, and 4.3) and second cross-section image features formed by intersections with layers L.1 . . . L.M, which include for example SiO2, SiN— or Tungsten lines. Some of the lines are also called “word-lines”. The maximum number M of layers is typically more than 50, for example more than 100 or even more than 200. The HAR-structures and layers extend throughout most of the volume in the wafer but may include gaps. The HAR structures typically have diameters below 100 nm, for example about 80 nm, or for example 40 nm. The cross-section image slices contain therefore first cross-section image features as intersections or cross-sections of the HAR structure footprints at different depth (Z) at the respective XY-location. In case of vertical memory HAR structures of a cylindrical shape, the obtained first cross-sections image features are circular or elliptical structures at various depths determined by the locations of the structures on the sloped cross-section surface 52. The memory stack extends in the Z-direction perpendicular to the wafer surface 55. The thickness d or minimum distances d between two adjacent cross-section image slices is adjusted to values typically in the order of few nm, for example 30 nm, 20 nm, 10 nm, 5 nm, 4 nm or even less. Once a layer of material of predetermined thickness d is removed with FIB, a next cross-section surface 53.i . . . 53.J is exposed and accessible for imaging with the charged particle imaging beam 44.

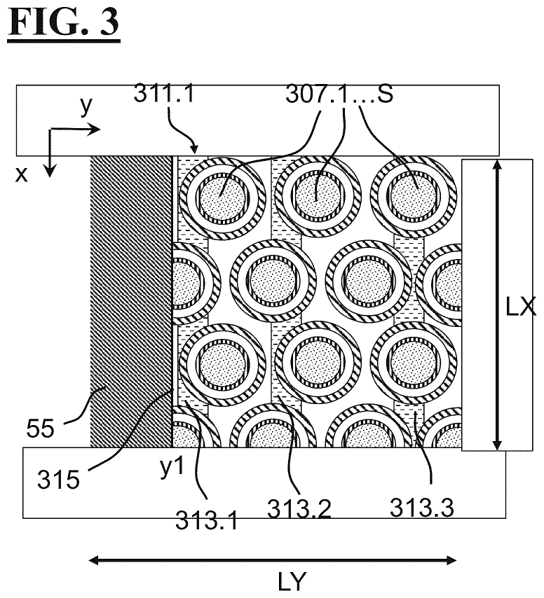

FIG. 3 shows an example of a cross-section image slice 311.1 generated by the imaging charged particle beam and corresponding to the cross-section surface 52. The cross-section image slice 311.1 includes an edge line 315 between the slanted cross-section and the surface 55 of the wafer at the edge coordinate y1. Right to the edge, the image slice 311.1 shows several cross-sections 307.1 . . . 307.S through the HAR structures which are intersected by the cross-section surface 52. In addition, the image slice 311.1 includes cross-sections of several word lines 313.1 to 313.3 at different depths or z-positions. With these word lines 313.1 to 313.3, a depth map Z₁(x,y) of the slanted cross-section surface 52 can be generated.

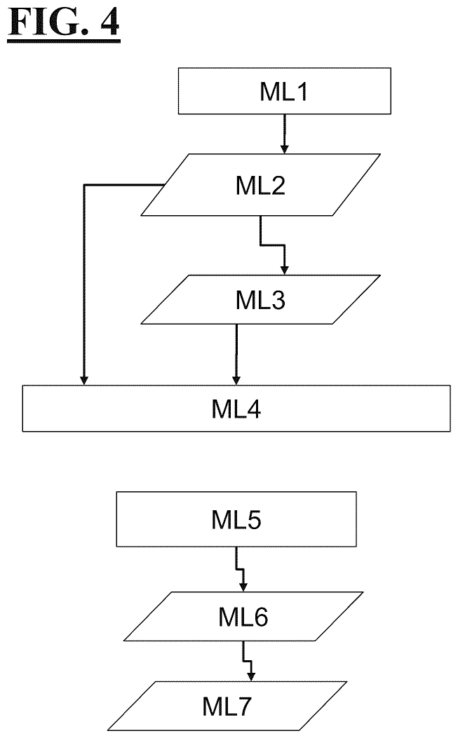

According to an aspect of the disclosure, a fast and robust method for performing a measurement task is provided. More details of the method for performing a measurement task are described below in the second embodiment of the disclosure, and s short description of the method is illustrated at the example of FIG. 4.

From a 3D-volume image data of high resolution (i.e., with a plurality of more than 100, preferable more than 1000 image slices), properties of included 3D structures can be determined, for example an averaged tilt angle of repetitive semiconductor structures, a minimum diameter, a distance, a bending, or an overlay error, and a plurality of image slices or virtual image splices can be extracted. With the plurality of image slices or virtual image slices, a first machine learning algorithm can be trained and a minimum set of cross-section images slices for the measurement of a property of a repetitive 3D structure can be determined. With a second machine learning algorithm, a property of a repetitive 3D structure can be determined from a minimum set of cross-section image slices with high accuracy and high throughput. The method is described by following steps.

In step M1, a plurality of high-resolution 3D volume images of a representative inspection volume is generated. The plurality of high-resolution 3D volume images can be generated either by a slice and imaging method applied to representative test wafers or can be generated by simulation, for example by varying a 3D volume image obtained by a measurement.

In step ML2, the property of interest of a repetitive semiconductor structures is determined from the plurality of high-resolution 3D volume images. Each high-resolution 3D volume image represents thus a specific property, described by a at least one parameter. The plurality of high-resolution 3D volume images is labelled with parameter values of the at least one parameter.

In step ML3, a plurality of labelled or annotated cross-section image slices is extracted or generated from the plurality of labelled high-resolution 3D volume images. The slices can be measured image slices or virtual image slices, computed from a high-resolution 3D volume image.

In step ML4, a machine learning model is trained with the plurality of annotated cross-section image slices and the plurality of labelled high-resolution 3D volume images. The training can be achieved iteratively to determine the desired minimum set of cross-section image slices and to determine the parameter values of interest with a given accuracy and confidence.

In step ML5, a set of measured cross-section image slices is determined, for example from a measurement at a new inspection site of a wafer.

In step ML6, the trained model according step ML4 is applied to the set of measured cross-section image slices.

In step ML7, the output of the parameter values and the confidence value according to the trained model is generated for the new inspection site of the wafer.

The method and the trained model can be improved by further iterations and adaption of the trained model to new inspection results at new wafers for measurement, including the generation of new 3D volume images by simulation, triggered for example by low confidence values according step ML7.

A preferred method for performing a measurement task is including one single contiguous machine learning algorithm. The contiguous machine learning algorithm is directly applied to images and a plurality of measurement results are obtained. A method of performing a measurement task by machine learning is generally described as an example in US 2020/0258212 A1, which is hereby fully incorporated by reference. According to the improvements provided by the disclosure, the regressor of the machine learning algorithm directly generates the measurement values of a plurality of HAR channels from a new 2D image. The contiguous machine learning algorithm is described below in the second embodiment. To perform a measurement task with one step consisting of a single, contiguous machine learning algorithm, a large amount of annotated training image data is involved. The annotated training image data is used to cover the desired measurement value range of the selected physical or geometrical parameters. During a segmentation step in certain known methods, pixels or voxels inside a 2D or 3D image are assigned to a selected structure. Training of a machine learning segmentation involves to provide pixel/voxel annotations for many pixels or voxels/in many images. This standard method of segmentation by user interaction and segmenting pixel by pixel is very time consuming-especially if you have precision properties like in semiconductor industry where sometimes structures are confined within only few 3-4 pixels.

According to a first embodiment of the disclosure, an improved segmentation and annotation method is provided to generate training image data for a measuring task with reduced used interaction. The method of generating training data according to the first embodiment relies on prior information. By using a priori information, the effort and especially any user interaction during generation of the training data is reduced to a minimum.

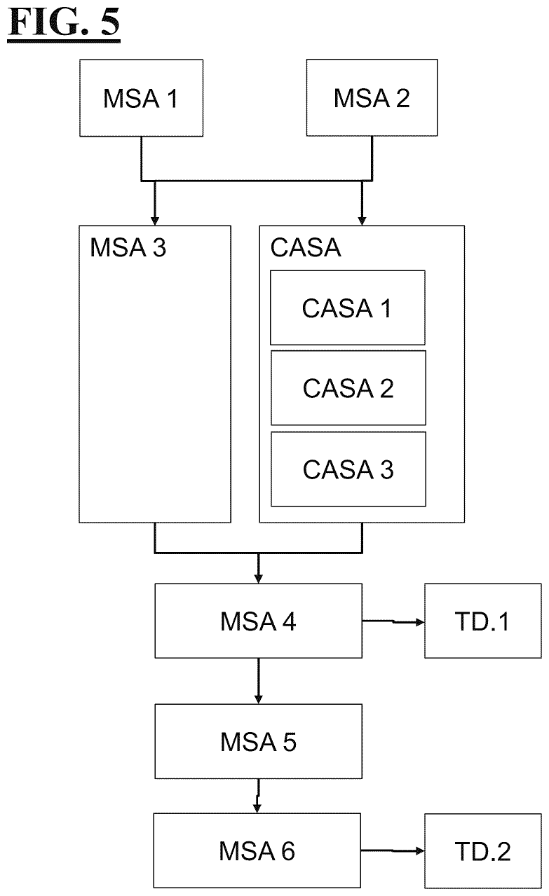

In a first example according to the first embodiment of the disclosure, the method includes a computer assisted method to generate the training data for a measuring algorithm. In the first example the generation of training image data is achieved by using a parametrized description of the semiconductor object of interest and the training image data is generated to cover the expected parameter value range to be measured. An example of elements of a parametrized geometrical description are the rings or shells of high-aspect-ratio (HAR) structures or HAR channels. The method is explained in FIG. 5.

In a first step MSA1, a first set of training images of an inspection site is obtained, for example the cross-section image 311.1 of FIG. 3, obtained by the dual beam charged particle microscope 1 described above. Each training image is including at least one cross section of the semiconductor object of interest, for example the cross sections of the HAR structures 307.1 to 307.S. At least a first image of the first set of training images is displayed via a user interface to a user.

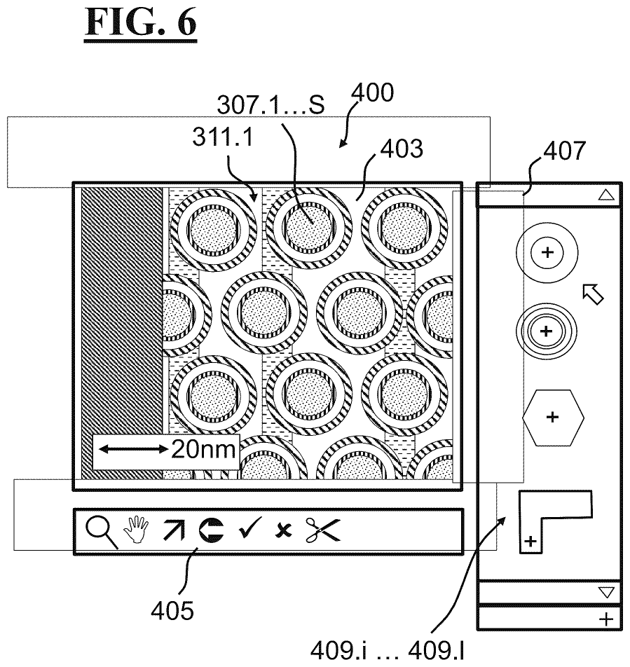

In a second step MSA2, a user selection of a parametrized description of the semiconductor object of interest is received. A parametrized description of the semiconductor object of interest can include geometrical shapes such as a circle, a ring, an ellipse, a polygon, or expansion coefficients of a series expansion, for example a Fourier series expansion, or the like. Parametrized description can be represented in different coordinate systems, for example cartesian or polar coordinates. The parametric descriptions can be selected from a library including typical user templates of parametric descriptions. An open list of parametric descriptions can be displayed via the user interface. In an example illustrated in FIG. 6, a user may select the number of four circular rings as a parametrized description 409.j, with the center coordinate and the four radii r1 to r4 of the circular rings. The user interface 400 illustrated in FIG. 6 includes an image display area 403, a toolbar 405 and a selection box 407 with a display of at least some graphical representations of predefined parametric descriptions 409.i . . . 409.1. The user interface is configured for graphical interaction with a user and can receive command about a selection of a parametric description. With elements of the toolbar 405, typical tools of graphical interfaces can be selected, for example a tool for a change of a magnification of the cross-section image 311.1 displayed in the image display area 403.

In a third step MSA3, a graphical representation according to the selected parametric description is displayed as an overlay over the training image on display of the user interface.

The user interaction is then limited to a change of few parameters of the parametric descriptions, for example a center position, a radius of a circle or to change the position of a point in a polygon instead of pixelwise annotation. The user interface is for example configured for a manual placement of the elements of graphical representation of the parametrized description and for manual selection of the parameter values.

As annotation values, the selected parameter values according to the selected parametric description are stored and serve as annotations to the respective training image. Step MSA 3 can be repeated for as many cross sections of HAR structures 307.1 to 307.S as desired.

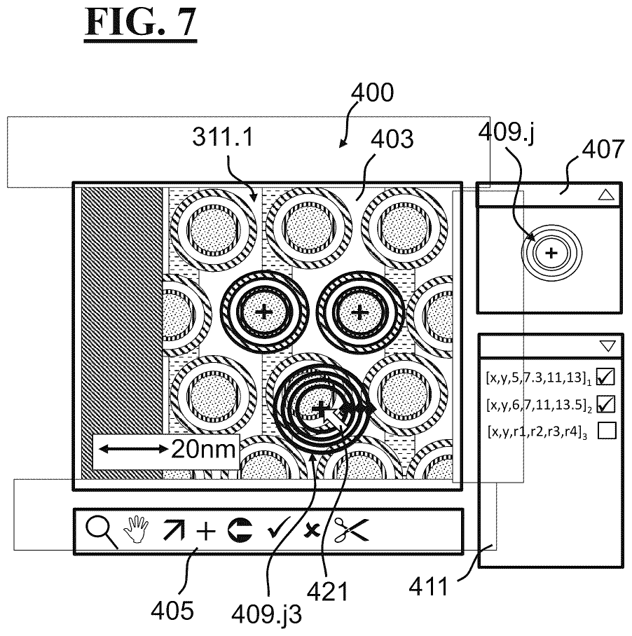

An example is illustrated in FIG. 7. The user interface 400 shows again in the image display area 403 a 2D image 311.1 to be annotated, the toolbar 405 and the selection box 407 with the display of the graphical representation of the selected parametric descriptions 409.j according step MSA 2. The user interface is configured for graphical interaction with a user and can receive command about a selection of the parameter values of the selected parametric description, in this example two coordinates of a lateral position in x and y and four radii of the circles. The user interface can be configured for graphical interaction as well as numerical input of parameter values. A user is assisted by the user interface display 400 and a user can easily detect edges or boundaries of HAR channels and adjust the circles of the parametric description accordingly. The measurement result is used as annotation label of the identified semiconductor object of interest. An example of a graphical representation 409.j3 of the selected parametric description is illustrated; the user interface is configured for graphical adjustment the position of the graphical representation 409.j3 and of the parameter values of the selected parametric description. The parameter values of the selected parametric description are displayed as tuples in list of annotation parameter values 411.

Generally, the determination of the parameter values to be measured relies on a known imaging scale or magnification of the cross-section image 311.1, which can for example be predetermined in a calibration step of the charged particle beam imaging system 40.

An exact determination of an imaging scale is however not involved, and the parameter values can also be given relative a constant scale of the training images.

Step MSA3 can be repeated for a plurality of the set of first training images and a plurality of training images with annotations is generated. The annotations include tuples of parameter values according to the selected parametric description. An example of a tuple [x,y,r1,r2,r3,r4] is illustrated in the list of annotation parameter values 411 for display of the tuples annotated to the actual training image. The list of annotation parameter values 411 includes in this example to accomplished annotations [x,y,5,7.3,11,13]₁, [x,y,6,7,11,13.5]₂, and one undetermined tuple [x,y,r1,r2,r3,r4]₃ according to the actual annotation with graphical representation 409.j3.

According to an example, the user interaction can be further reduced by computer assisted detection and positioning of instances of semiconductor objects of interest. In this example, the method according to the first example further includes a computer automated segmentation and annotation step CASA (see FIG. 5). During step CASA, instances of for example HAR cross sections are automatically detected and analyzed. The detection and analysis is based on the selected parametrized description and for example filtering algorithms. A processing algorithm can assist the user for a semi-automatic or automatic placement and adjustment of elements of the parametrized description, thereby readjusting the centers, radii and the like.

For example, in step CASA 1, repetitive instances of semiconductor objects of interest are determined by Fourier methods, and repetitive instances can be predicted from the raster positions derived from a filtered Fourier spectrum of an image.

In step CASA 2, initial annotation parameter values for each detected instance according step CASA 1 are automatically determined. The initial parameter values of the selected parametric description can be obtained by known image processing methods, such as correlation with matching filters or an application of a circular Hough transformation to directly detect the radius of a circle or the like. Generally, a Hough transform is a robust method to detect lines or circles, or general parametric descriptions of geometrical shapes. Matching filters can be generated automatically according to the selected parametric description. Other methods for example include for example contour detection methods. Thereby, at least same edges or boundaries of HAR channels can be detected and annotation parameter values can be determined. The annotation parameter values representing the measurement result are used as annotation label of the identified instance of the semiconductor object of interest. Other methods for the recognition of instances of the semiconductor object of interest and measurement of parameter values can for example employ a RANSAC algorithm.

In another example for the determination of initial annotation parameter values for each detected instance of a semiconductor objet of interest, a best fitting cross section of the semiconductor objet of interest is derived from the parametric description and information from CAD Data. Simulated cross section images of a semiconductor object of interest with different specific parameter values are generated by physically inspired forward simulation and are compared to the measured cross section. The parameter values of the parametric description most likely present in the measured image are determined by optimization. More about the physically inspired forward simulation will be described below.

In another example for the determination of initial annotation parameter values for each detected instance of a semiconductor objet of interest according step CASA 2, a matching step is applied. A matching step includes the determination of a matching term via a modified intersection-over-union-ratio (IoU). The IoU is known for determining the degree of similarity of two objects A and B, for example an object A in an image and an object class B used for the training data. According to an example of the disclosure, a modified IoU employs an area of maximum intersection, or overlap, among the bounded object and the selected parametric description. In an example, the exact determination of the IoU using the parametric description rather than surrounding rectangular bounding boxes can be applied. Thereby, an object detection is further improved.

In an example, the matching step includes computing a first intersection-over-union ratio based on the outmost bounding ring of the selected parametric description according to the example of HAR channels illustrated in FIGS. 6 and 7. Second and further intersection over union ratios can be computed iteratively based on the further parameters of the parametric description. However, it is also possible to match a bounded object in a single intersection over union-step to the plurality of parameter values of the parametric description.

In an example, the matching step can further include a step of computing a detection loss. Various algorithms of loss functions are known and are applicable to the present disclosure. However, instead of the usual modelling, the bonding box parameter loss according to the second embodiment of the disclosure is adapted to include predicted or “measured” parameter values and their corresponding L1 difference to the training data. Generally, the loss modelling for a predicted tuple versus an annotated tuple included in the training data can be composed by
(1) a classification loss,
(2) a bounding box parameter loss or confidence value, and/or
(3) a bounding box overlap loss

The parameter loss is described by an absolute deviation, for example a LI metric, between at least one parameter value of the predicted object and a corresponding annotated parameter value for the training data. In an example, the overlapp loss is described by a generalized intersection over union ratio based on a geometrical model according to the parametric description of the predicted object and the corresponding geometrical model of the training data. The bounding box overlap loss can be limited for example to only the outer bounding box of the largest ring.

The detection loss can include at least one, or a weighted sum of two or more of the detection losses. Other compositions of machine learning algorithms which detect objects by predicting their parametric representation are suitable as well. For example, an element of a parametric description, for example every circle of the selected parametric description according FIG. 7, can be subject to a separate, iterative object detection.

With the matching step, a forward model from a parametric description to a plausible image is provided and the parameter values for a best match of an image of for example a HAR channel cross-section are derived.

In step CASA 3, the graphical representations of the selected parametric description are graphically displayed via the user interface display 400 at the detected instances of the semiconductor object of interest as an overlay to the actual training image 311.1. Each graphical representation can be displayed according to the initial annotation parameter values derived in step CASA 2. The initial annotation parameter values can also be displayed in annotation parameter list 411. During step CASA 3, the user interface is configured to receive via a user input, a confirmation or a refinement of the initial annotation values. The user interface display 400 for confirmation or refinement can be similar to the user interface display 400 shown in FIG. 7. A completion or confirmation is for example illustrated by the checkboxes in the list of annotation parameter values 411, where the first two tuples are displayed as confirmed. With the computer automated segmentation and annotation step CASA 3, the user interaction is even further reduced.

The steps MSA 3 and CASA can be performed in parallel. A user can in parallel perform the segmentation and annotation according step MSA 3 and confirm or refine the results of the computer assisted segmentation and annotation in step CASA 3.

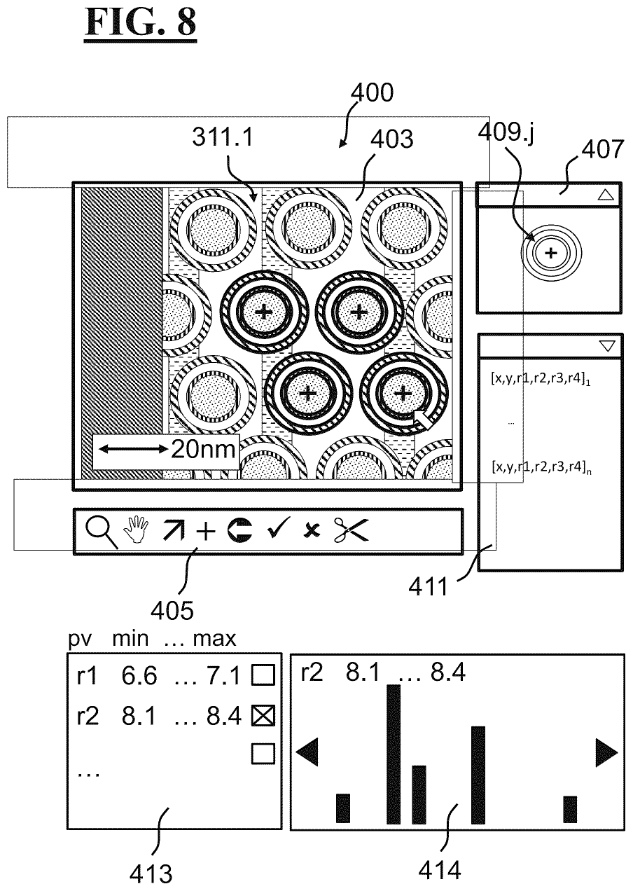

In a third step MSA4, a parameter value range of the annotated cross sections is evaluated and displayed. A user is thereby informed whether a desired parameter value range is already accomplished within the first set of training data. An example is illustrated in FIG. 8. The illustration can include a list of parameters 413 with minimum and maximum annotation values. In the example of FIG. 8, parameter values of parameter r2 is selected for further display in a histogram 414. Thereby, a user is informed about the parameter value range reached during the annotation method.

The set of training images is obtained from real cross section images from an inspection volume, and includes further semiconductor structures or objects, such as the word lines (reference number 313 in FIG. 3). The parametric description helps to segment and annotate the training images even in the presence of these further semiconductor structures. The machine learning algorithm trained with the annotated training images will therefore be robust even in presence of the further semiconductor structures.

At this point, a first set of training data TD.1 is generated and can be stored in a memory for further use. A set of training data TD typically includes a plurality of annotated training images and the parametric description, according to which the tuple including the annotation parameter values is interpreted. In the first set of training data TD.1, typically a limited range of measurement results of the parameter values are present. With a set of training cross section image segments, a first set of training data TD.1 of a limited parameter value range is generated. A machine learning algorithm or regressor, trained with the limited training data TD.1 is therefore capable of detecting and determining the continuous quantitative measures of the semiconductor structures of interest in a new image only within the limited parameter value range. Furthermore, for a metrology application, a quality measure of or for a machine learning algorithm can for example be defined by the deviation of an actually measured parameter value from a training or annotation parameter value. The quality measure can therefore be improved by utilizing a dense coverage of the predetermined parameter value range. Therefore, a large number of training data with a large number of annotations has to be generated. According to a second example of the method of the first embodiment, a coverage of the predetermined parameter value range is automatically improved by utilizing the first set of training images TD.1 obtained by user interaction during steps MSA 1 to MSA 4. For example, during step MSA4, the user interface can be configured to receive a user input including for example the desired parameter value ranges for the measurement task, or specific value ranges within the parameter value range, in which a better sampling with annotated training images is involved. During step MSA 5, further annotated training cross section image segments with different or additional parameter values within the specified parameter value range are generated from the first set of training images. Thereby, a second set of training images with different or additional parameter values can for example be generated by image processing. Example of suitable image processing includes at least one of a variation of a scale, a change of a shape, an interpolation, a morphologic operation, or a pattern substitution within a training image.

The first and second set of training images are combined in step MSA 6 to build the completed set of training image or training data TD.2. The segmentation and annotation result of set of training images can be further used for a mapping of the pixels of the 2D training images and a pixelated segmentation is achieved. The pixelated segmentation can further be utilized to for example combine a measuring machine learning algorithm with a defect detection and classification algorithm.

The completed set of training image or second training data TD.2 is finally stored in a memory for further use.

The generation of additional training images according step MSA 5 is however not limited to additional training images with different parameter values of a parametric description of a semiconductor object of interest. Further additional training images can include variations of parameters of the image acquisition, for example a noise level or an image contrast. Thereby, a machine learning algorithm trained with the second training data is more robust and provides measurement results with higher accuracy.

The system configured to perform the methods according to the second example of the first embodiment is thus also capable of quickly adapting to new measurement tasks of semiconductor objects of interest of different size or scale after for example a shrink of the integrated semiconductor structure. According to the second example, a set of training data is based on existing annotated training images, for example covering a narrow range of measurement values, or a different range or measurement values. Further annotated training images are generated by image processing of the annotated training images to cover a desired range of measurement values. This is for example useful when a shrink is applied to the semiconductor structures, or when a magnification of the imaging process is changed.

In FIGS. 3 to 8, the cross-section images and the training images are simplified for illustration purposes. As described above, cross-section images typically include hundreds to several thousand cross sections of HAR structures. The training images are typically much smaller than the actual measured cross section images and include for example only small numbers of HAS structures, for example less than fifty, or even less. Training images should furthermore have smaller pixel numbers, for example including only 256, 512, or 1024 pixels in one dimension. A training image can thus for example be formed by 256×1024 pixels or by 512×512 pixels. The training images are therefore typically formed by segments of the cross-section images. With the reduced pixel number, a fast and effective training of a machine learning algorithm is possible. However, with the advance of processors, also larger pixel numbers are possible, for example 2048 or 4096 pixels in one dimension.

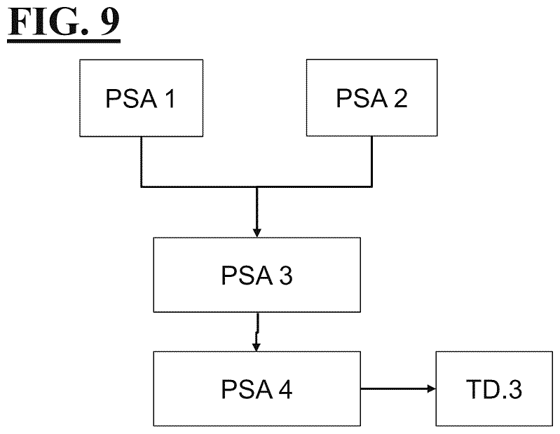

In a third example of the method according to the first embodiment, the user interaction is even further reduced. The method for generating training data for training of a machine learning algorithm for performing a quantitative measurement can generally be improved by a-priori knowledge. According to the third example of the first embodiment, the method of generating training data applies a physical simulation of the imaging process of a cross section through an inspection volume of a semiconductor wafer. The method is illustrated in FIG. 9.

In step PSA1, a user input about the expected cross section through an inspection volume of a semiconductor wafer is received. The expected cross section can for example be obtained from CAD information. CAD-data can for example be graphically displayed via a 3D-projection, and cross-sections through the CAD-information can for example be presented similar to FIG. 6 with the difference, that not an actual cross section image is displayed, but a cross section though CAD data. The interface is further configured for a selection of a parametrized description of the semiconductor object of interest. The parametric descriptions can be selected according to CAD data. In an example, the parametrized description used in CAD data of the semiconductor object of interest is directly applied. A plurality of instances of semiconductor objects of interest according to the parametrized description is generated, with material composition available from the CAD information. Thereby, a raw image is generated, which is used in later physical simulation of the image formation. For a set of training images, the parameter values of the parametrized description of the semiconductor object of interest are varied within a predetermined parameter value range, and a plurality of raw images is generated. A parameter value range can be specified by a user input, and the user interface is further configured to receive the parameter value ranges according to the parameters of the selected parametrized description. Further objects of the semiconductor, such as word lines, can be extracted from CAD-data and considered in the raw images for the generation of the annotated training images.

In step PSA 2, the imaging parameters of the charged particle beam imaging system (40) are determined. During this step, the user interface is configured to receive the user commands of how the measurement images at real inspections sites shall be obtained. The imaging parameters can be described within a typical setup, with which a charged particle imaging system is operated. Typically, charged particle imaging systems offer a set of predefined imaging setups, from which a user can select a task-specific imaging setup. For example, the imaging parameters desired for physical simulation include an electron energy, a pixel size, a scanning method, a dwell time, a setting of the charged particle beam imaging system, a selected contrast method, for example including a selected detector. These imaging parameters can be stored together with each of the imaging setups of the list of predefined imaging setups.

The imaging parameters further include a list of predetermined material contrasts. The imaging parameters are not only limited to the imaging but can for example further include parameters of the milling operation with the FIB beam 51. The imaging parameters can therefore further include an expected roughness or slope of a cross section surface. The imaging parameters can further include predetermined models of curtaining effects during milling operation.

Many of the imaging parameters can be previously determined and stored in look-up tables in a memory of the control unit of a charged particle inspection and metrology system, such as a system for performing an automated measurement of semiconductor objects. Some imaging parameters can be specific for a charged particle beam imaging system (40) and can previously been determined during a calibration step.

In step PSA 3, the physical-inspired forward simulation (short: physical simulation) of the imaging process for the given charged particle beam imaging system according step PSA 2 and the raw images according step PSA 1 is performed. The physical simulation can be performed in a processing engine of the charged particle inspection and metrology system or at any other processing engine with access to the information generated in steps PSA 1 and PSA 2.

The physical simulation typically includes a scaling or the raw image data to the images to be measured according to the pixel raster of the selected scanning method. A spatially resolved image contrast is determined by the material contrast of the materials present in the raw image data of the training images. After scaling and application of the material contrast values, a convolution of the raw image data with a convolution kernel according to the point spread function of the imaging system is performed. The point spread function can be determined according to an expected interaction volume generated by the primary charged particle imaging beam at a cross section through the wafer. The interaction volume typically depends on the electron energy. A noise level can be added according to the dwell time at each raster position. Thereby, also a limited detection count of a selected detector geometry is considered

The imaging parameters can further depend on the material composition within the inspection volume of the wafer and can include a curtaining effect of a milling operation according to a material composition in the cross section to be milled. Curtaining effects are accessible to simple models of the milling operation and can thus be considered as well. Milling effects generate for example an additional topography contrast, superposed on the material contrast.

The physical simulation can further consider additional structures within the inspection region, such as the word lines. Thereby, measurement effects of real images are considered in the training images.

In step PSA 4, a training image obtained by simulation can optionally be presented via a user interface for a user, and a user can for example reconsider the selections during steps PSA 1 or PSA 2. For example, a user may select a different magnification during imaging, or a different milling angle through the inspection volume. If a user requests any change, the process will repeat with step PSA 3. If a user confirms the simulated images, the method is completed. The annotated training images obtained by simulation are forming the set of training data TD.3 and are finally stored in a memory for further use. With the third example of the first embodiment, a large amount of training cross section image segments, covering the desired parameter value range, is automatically generated with minimum user interaction.

The general advantage of the segmentation and annotation method according to the first embodiment is a large reduction of the annotation effort by reducing the user interaction to a minimum. According to the first embodiment, the training data can be generated by either one of the examples described above, or by a combination of the examples. Thereby, a large amount of training data can be generated, including manually annotated training images, training images obtained by computer assisted segmentation and annotation, training images obtained by image processing, or training images obtained by physical simulation.

In an example, the generation of training image data is not completed after an initial training. Typically, not all effects or defects during manufacturing are foreseen in an initial training, and the training data of a machine learning algorithm is frequently modified during the monitoring of a manufacturing process. According to a fourth example of the first embodiment, a method is provided to further enhance the training data for a measuring task with reduced used interaction. For example, modified annotated training images can be provided to cover unexpected effects during the imaging process. Thereby, a machine learning algorithm for a measurement task is enhanced to extract further measurement results of measurement results with increased robustness versus deviations or aberrations.

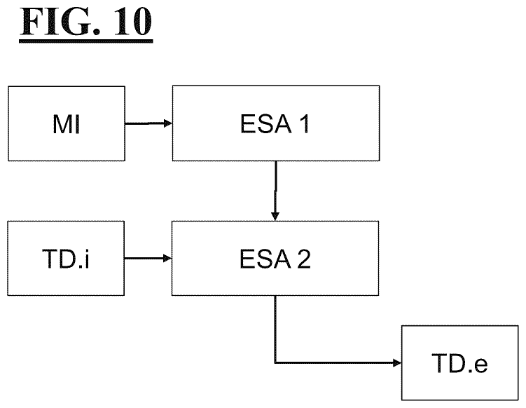

The initial annotated training data TD initially may cover only some effects of the image generation process, such as a magnification, a noise level, a material contrast, a convolution kernel such as an interaction volume. Imaging effects can for example be unexpected curtaining effects during a slice- and image process, leading to an unexpected topography contrast in addition to a material contrast of the SEM images. Such contrasts from curtaining can be considered in modified annotated training image data. Other effects are charging effects. Local sample charging has an influence on the local secondary electron yield and thus can change a material contrast and a primary particle beam focus position and thus generate locally distorted images or locally changed image contrast. Such images with locally changed image contrast and local distortion can be considered in modified annotated training image data. According to the fourth example, modified annotated training images are generated, for example according to the expected imaging parameter value range of the measuring task. The fourth example of the first embodiment for generating annotated training images is illustrated in FIG. 10.

During an inspection task, a plurality of cross section images MI in at least one inspection volume in a wafer are generated. The method of enhanced segmentation and annotation can be automatically triggered in step ESA1. For example, during a measurement method using the machine learning algorithm, a confidence value or quality measure of a measurement result is monitored. The machine learning algorithm is trained with the initial training data TD.i generated for example by any of the first to third example described above. An automated generation of further or modified annotated training images can be triggered, if a confidence value or quality measure of the measurement result frequently exceeds a predefined threshold. An automated generation of further or modified annotated training images can be triggered, if an image quality measure, such as a noise level or a contrast level, of the measured images frequently deviates from a predefined image quality measure.

A generation of further or modified annotated training images can further be triggered by user interaction. During a measurement task, at least one of the cross-section images is displayed via the user interface display 400 to a user and the user interface is configured to receive a user input to trigger the step of enhanced segmentation and annotation.

In step ESA 2, a method according to any of the first to third examples of the first embodiment, or a combination, can be applied for the generation of further or modified annotated training images. According to the first example, a further set of annotated training images is generated by computer assisted annotation of real measurement cross section images. According to the second example further or modified annotated training images are generated by image processing. According to the third example, further or modified annotated training images are generated by physical simulation, taking into account new or modified effects of the cross-section image generation, or taking into account modified raw images from step PSA 1 described above. In an example, modified annotated training image data is provided to cover unexpected effects during the manufacturing. During a measurement task, certain errors types can further be detected, for example regular and repetitive errors or defects from for example a contamination of a lithography mask. Other defects can be random, for example a sporadic contamination during a manufacturing process step. As a result of step ESA 2, enhanced training data TD.e is generated and stored in a memory for further use.

The segmentation and annotation method according to the first embodiment offers the further advantage to quickly adopt the parametrized description to a new semiconductor object or a deviation of the geometrical shapes of the semiconductor object of interest by introducing new, additional parameters in a selected parametric description. For example, if the HAR channels show a deviation from a circular shape, and additional parameter of for example an ellipticity or eccentricity can be introduced in an existing set of training data. The introduction can for example be performed in the refinements step or by automatic generation of additional training cross section image segments covering the parameter value range of the newly introduced parameter, for example an eccentricity. For example, if a material or material composition of a semiconductor object of interest is changed, the training data can automatically be adapted to the new material contrast corresponding to the new material or material composition.

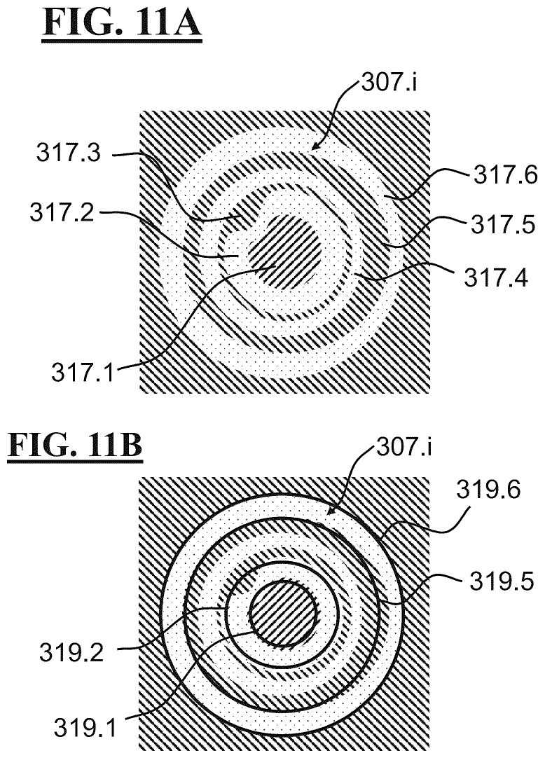

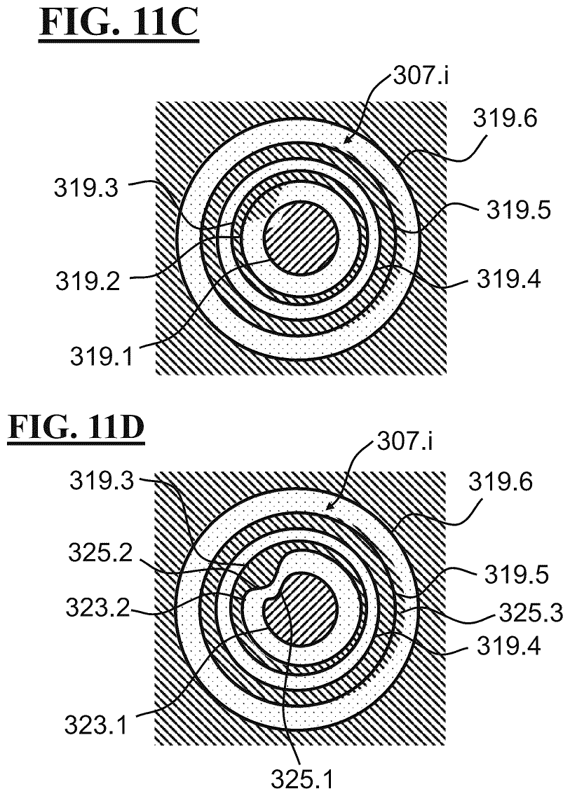

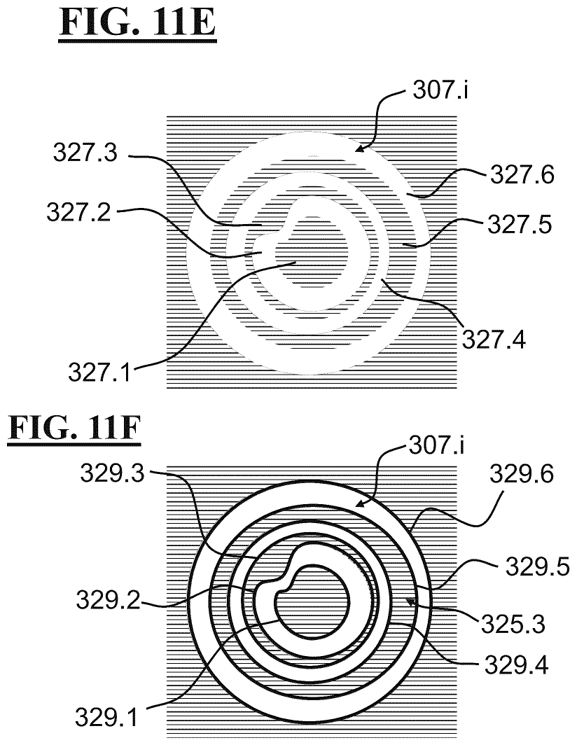

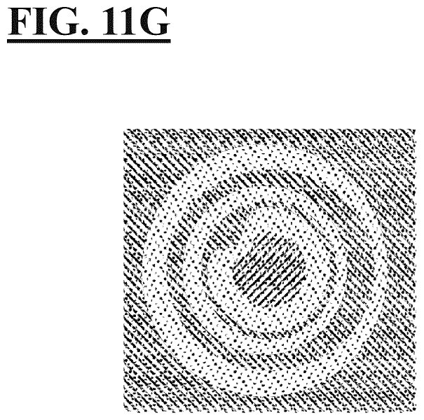

FIGS. 11A-11G illustrate a fifth example of the method of generating training data according to the first embodiment. According to the fifth example, an initial parametric description is selected according step MSA 2, and cross section images 311 are obtained as described in step MSA 1. FIGS. 11A-11G shows a cross section 307.i of an instance of a semiconductor object of interest within a cross section image 311, obtained by the dual beam device 1. The semiconductor object of interest of FIGS. 11A-11G is again a HAR structure, but other semiconductor objects of interest are possible as well. The illustrations of FIGS. 11A-11G are restricted to one instance of a cross section 307.i of a HAR channel.

In a first step, all instances of cross-sections of HAR-channels within a cross section image are identified, for example with the method described in step CASA 1 above. Each cross section 307.i includes one central circle 317.1 with five circles 317.2 to 317.6 with different image contrast (FIG. 11A).

In a second step, initial parameter values are automatically determined according step CASA 2, including the radii according to the selected parametric description. As illustrated in FIG. 11B, it can happen that not all geometrical shapes of a parametric description can be detected, and only circles 319.1, 319.2, 319.5 and 319.6 are automatically detected, while additional outer circles of circles 317.3 and 317.4 are not detected.

In a third step according CASA 3, wrong or missing annotations can be corrected by a user. The user interface is configured to receive commands to amend, delete or add annotations, similar to step CASA 3 described above. The result is shown in FIG. 11C, with all circles 319.1 to 319.6 according to the selected parametric description. The user interface can also be configured to dismiss an annotation completely.

In a fourth step, the user interface is configured to receive commands to amend the parametric description. The result of a graphical overlay is illustrated in FIG. 11D. In the example, the real cross section image includes three significant deviations 325.1 to 325.3 from the circles of the initial parametric description. For example, the user interface is configured to receive commands to amend an element of the parametric description into another element. In the example of FIG. 11D), the initial parametric description of circle 319.1 and 319.2 is amended into an amended parametric description of a spline curve or closed polygon line 323.1 and 323.2. Thereby, the deviation 325.1 and 325.2 to the ideal circles is minimized. The user interface is therefore configured to receive commands to amend a selected initial parametric description 319 into a selected amended parametric description 325, and to receive commands about an adjustment of parameter values of the amended parametric description 323.

In step 5, the parametric description, including the amended parametric description 323, is used to automatically generate a pixel-wise labels of the cross-section image. The result is shown in FIG. 11E. Each pixel is automatically labelled according to the ring segments 327.1 to 327.6. The processing engine is configured to perform the labelling according to the location of pixels relative to the amended parametric description 323. The processing engine can further be configured to perform the labelling according to a dominant or average grey value within each area defined by the amended parametric description 323 shown in FIG. 11d. Thereby it is possible to improve the labelling to cover further deviations, for example deviation 325.3.

In step 6, post-processing routines algorithmically optimize the pixel-wise annotations for example by snapping to strong edges or by smoothing labelled regions. The result is shown in FIG. 11F. A further amendment of the parametric description and a fine adjustment of parameter values according to the amended parametric description is derived. In the example shown in FIGS. 11B-11D, the circle 319.5 did not cover the deviation 325.3. This missing deviation is automatically corrected in step 6 by amending the parametric description “circle” into for example an ellipse with one additional parameter value, describing the numerical excentricity. Thereby, a final parametric description is automatically determined, and a training image is annotated by improved annotation parameter values with high precision.

In an optional step 7, the result is presented via the user interface to a user. The interface is configured to receive a confirmation or further amendments like step 4 or step CASA 3 described above.

In a further example of the automated determination of initial parameter values according step 2 or step CASA 2, a physical-inspired forward simulation model is applied for the initial proposal of parameters values. As described in the third example of the first embodiment above, a physical-inspired forward simulation model is given as a sequence of numerical methods that model the physical or optical measurement process with for example the charged particle beam imaging device 40 (see FIG. 1). The physical-inspired forward simulation model F is applied to a raw image generated according to a parametric description P of a semiconductor object with a selected imaging setting S of the charged particle beam imaging device 40. In an example, the parametric description P is given by a parametric description P[x,y,r1,r2,r3,r4,r5,r6,e1,e2,e3,e4,e5,e6,e7] with the radii ri of a HAR channel cross-section and the materials ei for the different rings corresponding to different material contrasts of the SEM imaging process. The materials are typically prior known and can be set to fixed values. However, it is also possible to work with unknown materials. The physical-inspired forward simulation model F is typically independent of the input model P.

The measured cross section image 311.1 is given by Y. Ideally, the simulation model F reveals the measured image Y=F(S; P) including noise. An unknown object described by parameter values of P may thus be obtained by optimization of a merit function M(P):

M(P)=∥Y−F(S;P)∥

with the input parameters given for example by random initial parameter values of the parametric description P and the selected imaging setting S. The initial parameter values can also incorporate existing information about expected radii of the HAR channel cross-sections, which can be available from different gold-standard measurements or a prior information. Initial parameter values for further optimization can also be determined according to the methods described above in step CASA 2. In such an example, initial parameter values are determined for example by image processing, and optimized parameter values are determined according to the optimization using the physical inspired forward simulation model F.

As a result of the optimization, the tuple of real parameter values [x,y,r1,r2,r3,r4,r5,r6] of the HAR channel cross-section in a measured image Y are obtained. Since the parameters of the parametric P description are often limited to include only few parameters, also classical optimizations methods like simulated annealing may be applied. In a further example, the parametric description P of a HAR channel cross-section can however include several additional parameters to describe any deviations of the circular shapes. An example is illustrated in FIGS. 11A-11G. To efficiently compute a solution for this optimization problem with many parameters to be determined, a method of Differentiable Programming can be applied. Such methods are well known in the art.

As described above, the optimization can be performed in an iterative manner starting with a simple parametric description of a semiconductor object of interest, and by increasing the complexity of the parametric description, e.g., using deviations of rings. Such a method is more robust compared to the example of using upfront a plurality of parameters according to a comprehensive parametric description.

Since the initial proposals of parameters can be verified and corrected according steps CASA 3 or step 3 and 4 described in the fifth example, and the training data can be generated which is more consistent. Since annotation proposals can be verified and corrected easily, a correction of training data can be performed not only by highly-skilled application experts.

It is understood that the examples and method steps of the first embodiment can be combined with each other. Thereby, user interaction is reduced to a minimum and a large set of annotated training images is generated by application of few user interaction and a-prior information. The user interaction is reduced to the selection of a parametric description, a desired parameter value range, and an imaging mode of the imaging device. Further user interaction may include few initial annotations, few amendments or corrections of automated annotations, few amendments of parametric descriptions, and confirmation of selected annotation results.

While the previous examples of the first embodiment are described for an annotation of training data TD with parameter values of semiconductor objects of interest, a method according to the first embodiment can also be applied to a segmentation method. During segmentation, cross section images of semiconductor objects of interest are typically annotated pixel per pixel. Thereby, different elements of a semiconductor objects of interest are labelled with a corresponding element identifier pixel by pixel within an image. For example, the rings of a HAR structure are labelled or annotated with their respective ring number. Such training images can then be used for training an object detection machine learning model. The pixel-wise annotation by a user is a very time-consuming method and prone to errors. With the parametrized description of semiconductor objects of interest, similar to the first embodiment, a segmentation workflow can involve less effort. The pixels of pixel-wise segmented training images are annotated according to the parametrized description with the properly adjusted parameter values by the method steps described above, for example by user selection of the parametrized description and reduced user interaction, or by image processing or physical inspired simulation and optimization. After annotating initial training images during an initial segmentation workflow, further pixel-wise annotated training images can be generated by image processing or physical inspired simulation. Thereby, with a method according to the first embodiment, a full image-segmentation can involve less effort, and training image data for a machine learning model for object detection can be generated with less user interaction.

The computational steps according to the examples of the first embodiment can be implemented in a system including a processing engine, configured to produce initial proposals for parameter values of parametric descriptions of semiconductor objects of interest. The algorithms, such as the physical-inspired forward simulation model, can be precompiled and stored as executables in the memory connected to the processing engine, ready for automatic execution or execution on demand.

According to the method described above, training data TD can be generated, by which a robust machine learning method can be trained. The machine learning algorithm, trained by the training data including parameter values as annotation values, is capable to perform a measurement even if new images are subject to high noise levels. An example of an image including a high noise level is shown in FIG. 11G.

In prior solutions, collecting and annotating a sufficiently large and diverse training data is extremely expensive, time consuming, and depending on the interaction with users. For example, the effort to manually annotate images of HAR channel cross-sections in a pixel-wise manner scales horribly poor especially in the presence of acquisition noise. However, with the methods according to the first embodiment of the disclosure, since no pixel-wise annotation is involved, training is enabled also to images including high noise levels.

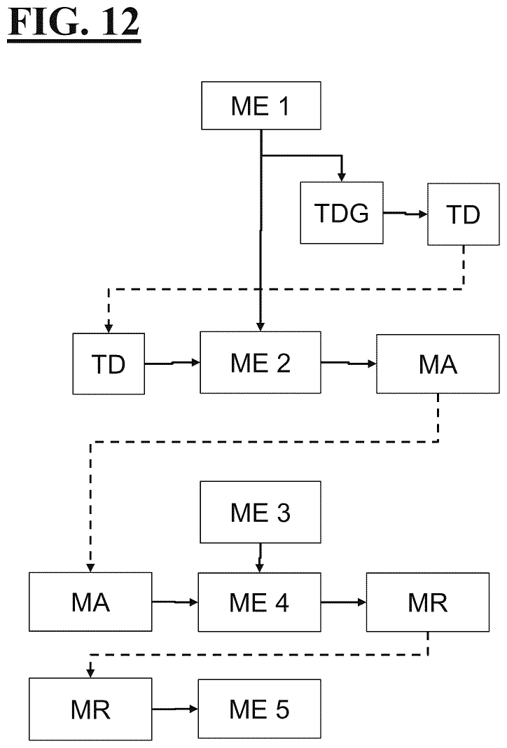

With the annotated training image data, a training of the machine learning algorithms for the measuring task can be achieved or modified and a measurement result can be obtained which is robust against defects or deviations. Further, the training data can further include identifiers to defect classes according to the certain error types. According to a second embodiment of the disclosure, a method of performing a measurement task of at least a parameter value of a plurality of semiconductor objects of interest by a contiguous machine learning algorithm is provided. As a result, the method of performing a measurement task extracts a list of parameter values of a plurality of semiconductor objects of interest in an inspection volume within a wafer. The parameter values represent the measurement results of the parameters of a parametric description, for example the four circles with four radii and the center position described above. For each instance of a semiconductor objects of interest, a tuple of parameter values, for example [x,y,r1,r2,r3,r4] is extracted as measurement result. In an example, measurement results are generated for each cross-section image of each HAR structure inside an inspection volume. The set of measurement results can include diameters, center positions offsets, areas, distances, ellipticities, or other general geometrical properties. The set of measurement results can also include the relative deviation from an expected parameter value according for example a design specification of a semiconductor object. The set of parameters can further include presumed material compositions or other physical properties of the manufactured semiconductor devices, or the number of instances of the repetitive three-dimensional structures within the region of interest. The measurement method according to the second embodiment is not a classical measurement by for example comparing with a scale or a reference, a counting, or by using classical measurement tools. An example would be a laser interferometer of a stage. In contrast to classical measurement, the measurement method according to the second embodiment relies on a properly trained and modified machine learning algorithm described below. The method according to the second embodiment is also called a measurement value extractor, and a measurement result is limited to the parameters of the parametric description used in the training data. The modified machine learning algorithm can be simplified as a regression, by which parameter values present in training data can be reproduced with high confidence, and parameter values which are not present in training data are measured with a lower confidence. The measurement of for example the channel cross-section properties of HAR channels is thus achieved by a trainable machine learning algorithm and no heuristic post-processing is involved. The method of a measurement value extractor according to the second embodiment is described in FIG. 12.

In step ME1, the measurement task is configured. A machine learning algorithm for the measurement task is selected. The selection can be received by a user interaction or can automatically been selected according to the parametric description used during the generation of the training data.

If no training data are available for the measurement task, a step TDG for training data generation is triggered. The step TDG can be configured according to the first embodiment of the disclosure. As a result, training data TD is generated and stored in a memory.

During step ME 2, the training data TD from the memory is used to train the selected machine learning algorithm. The trained algorithm MA is finally stored in a memory of for example a processing engine of a control unit of a metrology system. Once the machine learning algorithm has been trained to associate a tuple to each detected instance of a semiconductor object of interest, it is possible execute the trained machine learning algorithm on any new cross section image. The trained algorithm MA is then capable of detecting instance of a semiconductor object of interest and generated tuples of parameter values according to the selected parametric descrition used in the training images. The interpretation of the parameter values is linked to the selected parametric descrition.

In step ME 3, at least one new cross-section image slices is generated, for example at new inspection site of a wafer. The inspection sites are typically listed on an inspection list and can include typical locations of repeated inspection sites die by die or wafer by wafer. The inspection site of a wafer is placed by the wafer-table under a charged particle beam microscope and at least one cross section image is obtained. During a measurement task, for example a plurality of cross section images slices through an inspection volume is generated, for example by a slice- and imaging method. The method of image acquisition and the apparatus for image acquisition according to the slice- and imaging method is described in context of figures one to three of this application. As long as the new cross-section image slices during a measurement task are scaled with an identical or very similar magnification scale as the training images, tuples of representative measurement results according to the selected parametric description of a semiconductor object of interest can be generated as output and a measurement task can be performed. In this manner, geometrical characteristics of the cross section can thus be extracted with a single-step approach.

In step ME 4, the trained machine learning algorithm MA is applied to the at least one new cross-section image slices and the measurement result is obtained. The measurement results include a list of tuples of extracted parameter values of the detected instances of semiconductor objects of interest and a confidence value for each of the extracted parameter values. The measurement result MR is stored in a memory for further use. It is understood that the steps ME 3 and ME 4 can be repeated a plurality of times for a plurality of cross section images, for example at different depths inside the inspection volume resulting from the slice- and image method. Thereby, a plurality of measurement result MR is stored in a memory for further use

Machine learning algorithms typically include a sequence of layer, including an input layer, an output layer, and so-called hidden layers. The hidden layers include a sequence of abstract mathematical operations, which are for example available from established libraries for programming machine learning algorithms. A machine learning algorithm as applied in the second embodiment is known as object detection. Object detection is typically implemented as a convolutional neural network (CNN). A CNN according to the disclosure has for example 10 to 200 convolutional layers followed by 1 to 3 fully connected layers. The convolutional layers are not limited to convolutions, but may include also non-linear operations such as normalization, pooling or skipping operations. Typically, the output of an object detection operation is a list of tuples, each tuple including the five values corresponding to bounding box parameters position x, y, width and height, a class label, and a confidence value.

An example of a modified machine learning algorithm according to the second embodiment is including the YOLO (“you only look once”) method as object detection method, which is known in the art. According to the YOLO-method, a machine learning algorithm “only looks once” at an image to predict where objects are present, together with a classification label and a confidence value. With a single object detection network, such a machine learning algorithm predicts simultaneously bounding boxes and class probabilities. Another example of an object detection according to the second embodiment is the “detection-transformer” or DETR-method, which is well known in the art. Within the DETR method, set of predictions (or measurement results) are directly generated in parallel. The DETR uses a conventional CNN in combination with a transformer-encoder and a transformer-decoder, which are both known in the art. Transformer based architectures are originally used in the field of natural language processing. They can handle non-local correlations efficiently, e.g., to connect the correlation of words in a sentence to extract their correct meaning. In image processing this leads into the possibility to correlate non-local information. Thereby, an “order” or a semantic contest of pixels is determined and a detection of for example a first object of a parametric description increases the probability to detect further objects of the parametric descrition, e.g., a detected ring in an image increases the probability to detect the further rings of a HAR-channel in the neighborhood.

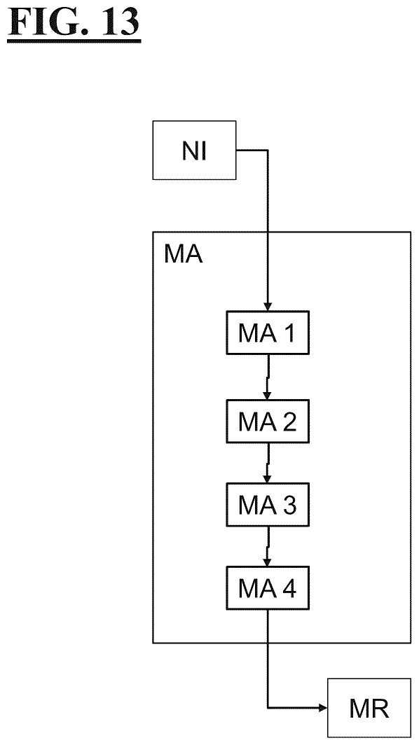

An schematical illustration of a modified machine learning algorithm MA is illustrated in FIG. 13. In a step MA 1 the new cross section image NI is received. A new cross section image NI image can include imperfections such as defects or noise and deviations from the parameter values of the training data. In an example, the received cross section image NI is improved, for instance by applying image processing algorithms such as any of convolution, normalization, filtering, edge handling, etc. The purpose of step MA 1 can thus be to pre-process the new cross section image NI to allow the trained machine learning algorithm to operate more efficiently.

In a step MA 2, one or more instances of semiconductor objects of interest in the new cross section image NI are detected. The detection is configured so that each instance of an detected object includes image characteristics corresponding to the selected parametric description of the training image data. The output of step MA 2 can include one or more bounding boxes, at least some of which include an instance of semiconductor objects of interest, preferably most of them, most preferably all of them. One or more of the bounding boxes, most preferably each bounding box, can include a class label and/or a confidence level associated to the bounded object. The association of a class label and and/or a confidence level with the bounded object can be implemented via known algorithms.

In an optional filtering step MA 3, bounding boxes outputted by step MA 2 can be filtered based on their confidence level. This allows to select bounding boxes with a confidence level higher than a predetermined threshold for the subsequent steps. The steps MA 2 and MA 3 therefore allow an identification and selection of bounding boxes including instances of a semiconductor object of interest with high probability. Each bounding box thus includes a new, real image of the cross section of a semiconductor object of interest, for example a cross section trough an HAR channel.

In a step MA 4, a predicted tuple of parameter values is generated for the at least one semiconductor object of interest within a bounding box. Each predicted tuple for each instance of a detected semiconductor object of interest corresponds to the tuple used during the training of the training data and includes for example center coordinates and the measurement results of for example four radii of a HAR channel, and a confidence value. Other tuples corresponding to the selected parametric description are possible as well.

The steps MA 2 to MA 4 are illustrated here as consecutive steps for the purpose of a simplified illustration. It is understood that machine learning algorithms will perform the functions of step MA 2 to MA 4 in an entangled manner.

The tuples generated by the modified machine learning algorithm MA thus are including a plurality of parameter values of a measured semiconductor object. Instead of attempting to measure geometrical characteristics from the new cross section image NI of the bounded objects, the method of performing a measurement task according to the second embodiment employs a modified machine learning algorithm MA, which matches the detected instances of semiconductor objects of interest with predicted parameter values according to the parametric description used during the training of the modified machine learning algorithm MA.

According to the second embodiment of the disclosure, an output of an object detection operation is modified to include the tuple of parameter values defined in the selected parametric description. The output of the object detection operation is thus a direct prediction of at least on tuple of measurement values for each detected instance of a semiconductor of interest within a cross section image. Every predicted tuple represents the measurement or parameter values of one instance of a detected semiconductor object of interest. Since the parametric description corresponds to a “condensed” representation of a semiconductor object of interest, the noise on individual pixels or deviations of the semiconductor object of interest from the parametric descrition do not heavily affect the prediction quality of the object detection. The tuples further can further include an object classifier “object/no object” or a classifier for distinguishing several objects with different parametric descriptions. As an example, each tuple includes the center coordinates of an instance of a semiconductor object of interest and the four radii illustrated in FIGS. 6 and 7. The tuples correspond to the annotation tuples used during the generation of the training data, for example according to the first embodiment of the disclosure.

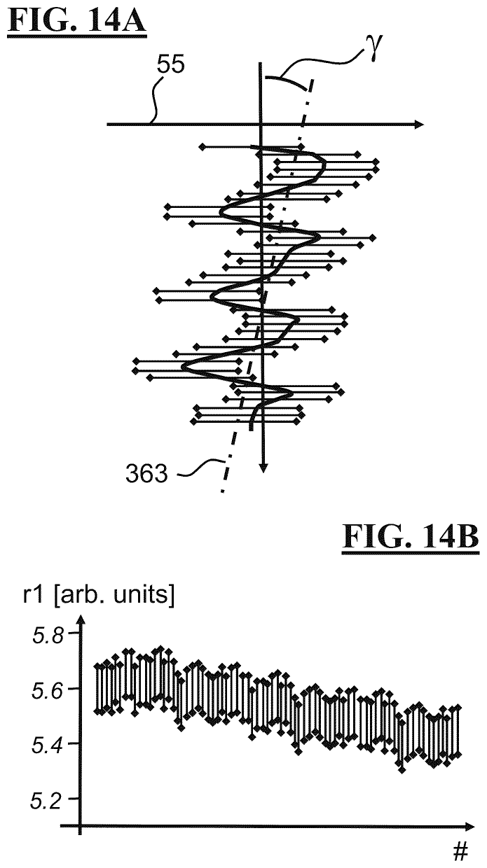

In an optional step ME 5 (FIG. 12), the measurement result MR stored in memory is further analyzed, for example a statistical analysis is performed, or a graphical display is generated. An example is illustrated in FIGS. 14A-14B. In FIG. 14A, a typical z-dependency of an average center position of an HAR structure or channels is known from a 3D volume inspection at a representative inspection position or reference position. The average HAR channel trajectory 363 (dotted line) is derived from the distribution of center positions x and y at different depth level z. FIG. 14B illustrates a measured parameter value, here at the example of r1 over a number (#) of instances of semiconductor objects of interest. As illustrated in FIGS. 14A-14B, each parameter value can be displayed with its confidence value.

According to the second embodiment, machine learning methods are utilized to accomplish a metrology or measurement task, providing a continuous measurement result. The second embodiment thus provides a fast, robust and adaptive measurement value extractor.

According to an aspect of the method according to the second embodiment, the method is further configured for generating modified annotated training image data during a monitoring task and configured for an additional training with the modified annotated training image data. As illustrated in FIG. 12, the step of generating or enhancing training data during step TDG, and the step of training or retraining the machine learning algorithm to accomplish the measurement task can be performed in parallel to a measurement task during step ME 4.

The method of the second embodiment is configured for a minimum user interaction during a measurement or inspection task. The measurement method utilizing one contiguous machine learning algorithm offers the advantage of being highly robust against imaging variations and can operate at high noise levels, where classical measurement methods fail. The method can be implemented to perform very fast. Furthermore, since no complicated physical simulation models of dedicated classical metrology methods are implemented, the method can easily be adapted to a variety of semiconductor objects of interest, including changes of a semiconductor object of interest, or changes of the imaging condition of the charged particle imaging system.

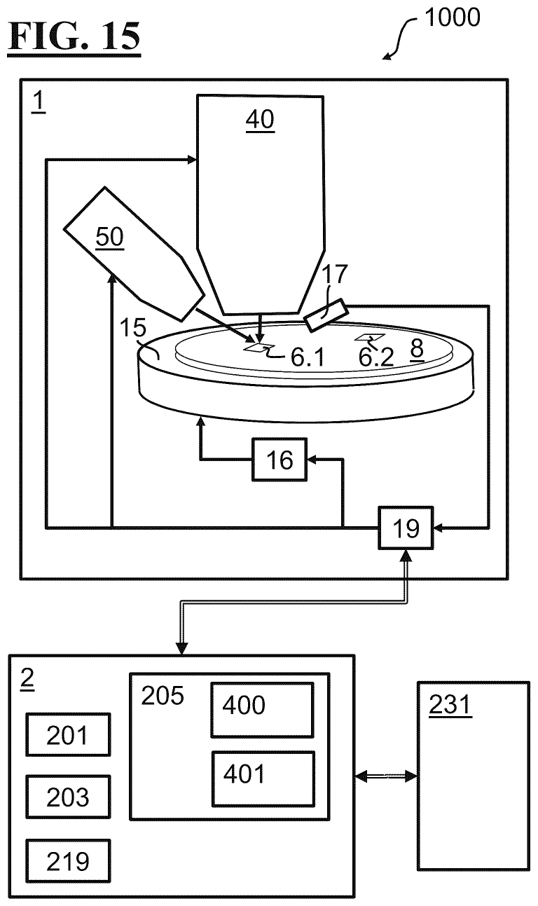

A system configured for implementing the measurement method according to the second embodiment is described in the third embodiment. A system configured for performing a measurement task by machine learning is illustrated in FIG. 15. The system for performing a measurement task 1000 is including a dual beam system 1. A dual beam system is illustrated in FIG. 1 with more detail and reference is made to the description of FIG. 1. Features of a dual beam system 1 include a first charged particle or FIB column 50 for milling and a second, charged particle beam imaging system 40 for high-resolution imaging of cross section surfaces. A dual beam system 1 includes at least one detector 17 for detecting secondary particles, which can be electrons or photons. A dual beam system 1 further includes a wafer support table 15 configured for holding during use a wafer 8. The wafer support table 15 is position controlled by a stage control unit 16, which is connected to the control unit 19 of the dual beam system 1. The control unit 19 is configured with memory and logic to control operation of the dual beam system 1.

The system for performing a measurement task 1000 is further including a operation control unit 2. The operation control unit 2 includes at least one processing engine 201, which can be formed by multiple parallel processors including GPU processors and a common, unified memory. The operation control unit 2 further includes an SSD memory of storage 203 of for example 8 TB or more for storing the training data generated during a training method, the trained machine learning algorithm, and a plurality of cross section images. The operation control unit 2 further includes a user interface 205, including the user interface display 400 and user command devices 401, configured for receiving input from a user. The operation control unit 2 further includes a memory or storage 219 for storing process information of the image generation process of the dual beam device 1. The process information of the image generation process with the dual beam device 1 can for example include a library of the effects during the image generation and a list of predetermined material contrasts.

The operation control unit 2 is further connected to an interface unit 231, which is configured to receive further commands or data, for example CAD data, from external devices or a network. The interface unit 231 is further configured to exchange information, for example the measurement results MR, with external devices, and to store a set of training data or a trained machine learning algorithm or plurality of cross section images in external storages.

The processing engine 201 is configured to consider process information of the image generation process with for example a dual beam device 1, including for example selected imaging parameters of the dual beam system. The imaging parameters can for example be selected by a user according to a desired speed or accuracy of the measurement task.

The system 1000 according to the third embodiment is configured to receive user information about the measurement task, for example including CAD information of the inspection volume or expected ranges of the desired measurement value ranges. The system 1000 is configured to combine the user information with process information of the image generation process. The processing engine 201 is configured to combine user and process information, and to generate training data TD with reduced user interaction. For example, the processing engine 201 is configured to generate annotated training images by physical simulation or image processing. In an example, the processing engine 201 is configured to generate training image data by physical simulation, based on CAD-models of the three-dimensional semiconductor structures. The user interface 205 is thus configured to receive, display and select CAD data. The processing engine 201 is further configured to consider material contrast, for example by a predetermined and stored library data of secondary electron yields for the specific material composition of semiconductor objects of interest. The processing engine 201 is further configured to consider an imaging noise according to a secondary electron collection efficiency and a dwell time according to the imaging parameters and the material composition of semiconductor objects of interest.

The processing engine 201 is further configured to train a selected machine learning algorithm with the training data stored in storage 203, and to store the trained machine learning algorithm MA in storage 203 for later use.

According to the third embodiment of the disclosure, a system 1000 for measuring parameter values of semiconductor objects in an inspection volume with high throughput is provided. The processing unit 201 is therefore configured for measuring a plurality of parameter values inside of an inspection volume of a semiconductor wafer according to a method of the second embodiment. The computing or processing unit 201 is configured for operating and processing the digital images of the series of cross-sections surfaces according to a trained machine learning algorithm MA, which is stored in storage 203, and providing the extracted measurement results MR via the user interface 205 or via interface unit 231.

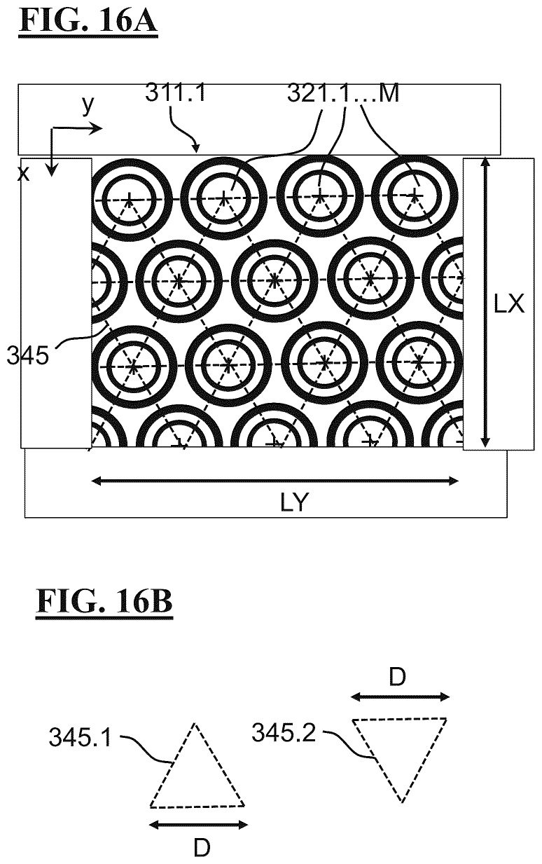

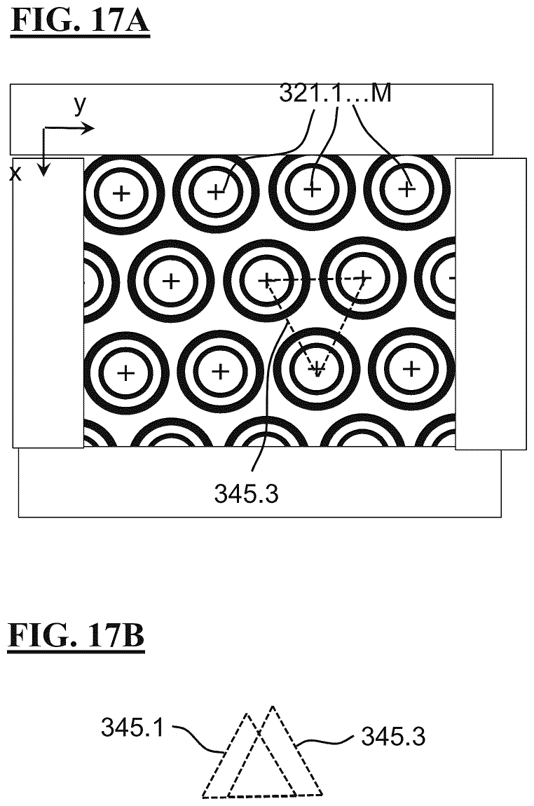

During the foregoing examples, the method according to the first or second embodiment have been applied to the measurement of parameter values of a parametric description of HAR channels. The methods can of course also be applied to other repetitive semiconductor objects of interest. The methods can further be applied for example to a raster of repetitive semiconductor objects of interest. An example is illustrated in FIGS. 16A-16B. FIG. 16A illustrates a cross section image slice with ideal raster configuration 345 of HAR channel cross sections. Each of the M HAR channel cross sections can for example be described by the parametric description including four circles with radii r1 to r4 and a center position 321.1 . . . . M. Furthermore, the parametric description of this example includes at least one raster unit cell, for example raster unit cells 345.1 and 345.2 illustrated in FIG. 16B. With the raster unit cells, a distance of a regularity of the HAR channel cross section in the cross-section image slice can be described. The unit cells can be included in the parametric description similar to other parametric descriptions, with the unit cell distance D as parameter. During the training according to the first embodiment of the disclosure, training images with different parameter values for the unit cell distance D are annotated, such that the annotation tuples of the training data further includes a plurality of different parameters values for parameter D. FIG. 17A shows an example of a cross section image slice with a deviation from the ideal raster configuration 345 of HAR channel cross sections. As illustrated in FIG. 17B, the unit cell 345.3 of this example has a larger parameter value for the unit cell parameter D. During a method according to the second embodiment, the parameter value D is included in the tuples of extracted measurement results from a new cross section image. The method according to the disclosure by utilizing parametric descriptions is therefore not limited to parametric descriptions of shapes or forms of semiconductor objects of interest, but also applicable to abstract parametric descriptions, including relations between semiconductor objects of interest, for example distances or regularities. Thereby, computational effort in the numerical analysis of measurement results can be reduced.

The disclosure provides a device and a method for 3D inspection of an inspection volume in a wafer and for the measuring of parameter values of semiconductor objects inside of the inspection volume with high throughput, high accuracy and reduced damage to the wafer. The method and device can be used for quantitative metrology, but can also be used for defect detection, process monitoring, defect review, and inspection of integrated circuits within semiconductor wafers. The disclosure is generally based on the concept that, instead of applying a 2- or more-step approach, a measurement result is obtained by application of a single, properly trained machine learning algorithm. The known 2- or more-step approach first applies a segmentation by conventional machine learning, and then computing-based on the output of the segmentation-geometrical characteristics such as the parameter values by classical methods of image processing and metrology. With the disclosure, the second step is avoided at the expense of generating more elaborated training data. The disclosure thus provides a method and a device for generating training data with reduced user interaction. The method and a device for generating training data relies on prior knowledge of the objects to be measured and a training can be achieved without recurring to for example pixel-wise segmentation. According to the disclosure, geometrical characteristics can be obtained directly from an input image, with a single-step approach without classical methods of image processing and metrology, including heuristically motivated computations. Instead, embodiments of the disclosure allow a measurement of parameters values of a semiconductor object of interest with a single-step process.

According to the disclosure, a system or device and a method for measurement of parameters of semiconductor wafers with increased throughput is provided. The system and the method provide higher flexibility and robustness during a measurement task and involve during implementation less effort compared to classical methods. The system and a method for measurement of parameters of semiconductor wafers can easily adapted or modified and can be accomplished with minimum user interaction. One feature of the system and method is application of prior knowledge, for example given by CAD information or by the given image properties of a charged particle beam imaging system.

The system and method rely on a parametric description of semiconductor objects of interest. Thereby, user interaction is reduced to a minimum, and the parameter values of are directly obtained by the modified machine learning algorithm according to the disclosure. While exhaustive classical methods for metrology are rather exploited, the application of machine learning for measurement tasks con further benefit from future improvements of the rapidly growing libraries and tools for machine learning. A system and method for measurement of parameters of semiconductor wafers according to the disclosure may further benefit from further developments in machine learning in the classical areas of machine learning.

The disclosure described by the embodiments can be described by following clauses:
Clause 1: A method of generating training data for training of a contiguous machine learning algorithm for providing quantitative measurement results of a parameter of a semiconductor object of interest from cross section images generated by a charged particle beam system, the method including:
   generating a set of training cross section image segments of the semiconductor object of interest, the training cross section image segments including a variation of a parameter value of the semiconductor object of interest,
   wherein the variation of the parameter value is within a selected parameter value range.
Clause 2: The method according to clause 1, further including the step of selecting a parametrized description of the semiconductor object of interest, the parametrized description is including the parameter.
Clause 3: The method according to clause 2, wherein the parameter of the parametrized description of the semiconductor object of interest is a length, a diameter, a distance, an area, an angle, a radius, an ellipticity, an aspect ratio, a curvature, a periodicity, a polygon parameter.
Clause 4: The method according to clause 2 or 3, wherein the step of selecting the parametrized description includes the step of presenting via a user interface a plurality of parametrized descriptions for selection and configuring of the selected parametrized description via a user input.
Clause 5: The method according to any of the clauses 1 to 4, further including the step of receiving imaging parameters of the charged particle beam system.
Clause 6: The method according to clause 5, wherein the imaging parameters include at least one of a resolution, a contrast, and a noise level.
Clause 7: The method according to clause 6, wherein the imaging parameters further include at least one of a point spread function, a dwell time, a contrast method, a material contrast, and a topography contrast.
Clause 8: The method according to any of the clauses 1 to 7, further including the step of receiving the selected parameter value range via an user input.
Clause 9: The method according to any of the clauses 1 to 8, wherein step of generating the set of training cross-section image segments further includes the step of annotating a plurality of cross section images including the semiconductor object of interest with the at least one annotation value, wherein each annotation value is representing a measurement result of the parameter at each detected instance of the semiconductor object of interest.
Clause 10: The method according to any of the clauses 1 to 9, wherein the step of generating the set of training cross section image segments includes the step of receiving at least a first set of training cross section image segments of the semiconductor object of interest from the charged particle beam system, the first set of training cross section image segments covering a first parameter value range.
Clause 11: The method according to clause 10, further including the step of automatically detecting, based on the selected parametrized description, instances of the semiconductor object of interest in the first set of training cross section image segments
Clause 12: The method according to clause 11, further including the step of automatically determining an initial annotation value for each detected instance of the semiconductor object of interest in the first set of training cross section image segments.
Clause 13: The method according to clause 12, wherein the step of automatically determining the initial annotation value includes the step of application of a physical simulation model to a parametric description of the semiconductor object of interest and a step of determining the parameter values of the parametric description by optimization.
Clause 14: The method according to clause 12 or 13, further including the step of graphically presenting, at at least one detected instance of the semiconductor object of interest within the first set of training cross section image segments, the parametrized description with the initial annotation value via a user interface.
Clause 15: The method according to clause 14, further including the step of receiving, via a user input, a confirmation or refinement of the initial annotation value.
Clause 16: The method according to any of the clauses 10 to 15, wherein the method includes the step of comparing the first parameter value range with the selected parameter value range, and the step of determining, depending on the comparison result, whether further training cross section image segments are involved.
Clause 17: The method according to clause 16, wherein the step of generating the set of training cross section image segments includes the step of generating a second set of training cross-section image segments of the semiconductor object of interest within a second parameter range from the first set of training cross section image segments by image processing.
Clause 18: The method according to clause 17, wherein the image processing includes at least one of a variation of a scale, a change of a shape, an interpolation, a morphologic operation, a pattern substitution.
Clause 19: The method according to clause 16, wherein the step of generating the set of training cross section image segments includes the step of generating a second set of training cross-section image segments of the semiconductor object of interest within a second parameter range by physical simulation of cross section image segments based on the selected parametrized description of the semiconductor object of interest and imaging parameters of the charged particle beam system.
Clause 20: The method according to any of the clauses 1 to 19, wherein the step of generating the set of training cross section image segments includes a physical simulation of cross section image segments based on a-priori information of the semiconductor object of interest and imaging parameters of the charged particle beam system.
Clause 21: The method according to clause 20, wherein the physical simulation includes a step of receiving CAD data of the semiconductor object of interest and selecting the parametrized description of the semiconductor object of interest according to the CAD data;
a step of varying the CAD data according to the selected parameter value range of the parametrized description;
a step of performing a physical simulation of the imaging with the charged particle beam system in order to obtain the set of training cross section image segments.
Clause 22: The method according to any of the clauses 1 to 21, wherein the training data is configured for training of a machine learning algorithm for providing continuous quantitative measure of the parameter of the semiconductor object of interest.
Clause 23: A method of performing measurements of semiconductor objects within a wafer, including the steps of
   obtaining a digital 2D cross section image slice including at least one cross section of a semiconductor object of interest,
   determining at least one quantitative measurement result of at least one predefined parameter of the semiconductor object of interest by one contiguous machine learning algorithm directly applied to the digital 2D cross section image slice.
Clause 24: The method according to clause 23, wherein the at least one predefined parameter is a parameter of a parametrized geometrical description of the semiconductor object of interest.
Clause 25: The method according to clause 24, wherein the at least one predefined parameter is one of a dimension, a length, a diameter, a distance, an area, an angle, a radius, an ellipticity, an aspect ratio, a curvature, a periodicity, a polygon, or the like.
Clause 26: The method according to any of the clause 23 to 25, wherein the step of determining the quantitative measurement result includes the step of determining a continuous quantitative measure of the at least one predefined parameter.
Clause 27: The method according to clause 26, wherein the step of determining the quantitative measurement result further includes a measurement of the quantity or instances of the semiconductor object of interest.
Clause 28: The method according to clause 26 or 27, wherein the step of determining the quantitative measurement result further includes the determination of a continuous quantitative measurement result of the predefined parameter for each of a quantity or instances of the semiconductor object of interest.
Clause 29: The method according to any of the clauses 23 to 28, wherein the 2D cross section image slice is obtained by a charged particle beam system including at least one charged particle beam column.
Clause 30: The method according to any of the clauses 23 to 29, wherein the 2D cross section image slice is one of a plurality of 2D cross section image slice obtained by a slice- and image method including repeatedly milling and imaging a plurality of 2D cross section image slices through an inspection volume in wafer.
Clause 31: The method according to any of the clause 23 to 30, further including the step of training of the contiguous machine learning algorithm by training data.
Clause 32: The method according to any of the clause 23 to 31, further including the generation of training data according to the method steps of any of the clauses 1 to 22.
Clause 33: the method according to any of the clause 23 to 32, wherein the semiconductor object of interest is at least one HAR channel within a wafer, and wherein the parametrized description includes a set of rings or circles.
Clause 34: A system for performing an automated measurement of semiconductor objects in a wafer, including
   a charged particle beam system including at least one charged particle beam column, configured for obtaining at least one 2D cross section image slice;
   a control unit in communication with the charged particle beam system, the control unit further including:
   a user interface configured for display of information and receiving a user input;
   a processing engine configured for determining during use at least one quantitative measurement result of at least one predefined parameter of a semiconductor object of interest by one contiguous machine learning algorithm directly applied to the digital 2D cross section image slice.
Clause 35: The system according to clause 34, wherein the processing engine is further configured for training the one contiguous machine learning algorithm with training data including a set of annotated training cross section image segments of the semiconductor object of interest.
Clause 36: The system according to clause 34 or 35, wherein the processing engine is further configured for generating the training data according to any of the method steps of any of the clauses 1 to 22.
Clause 37: The system according to any of the clauses 34 to 36, wherein the processing engine is configured for performing measurements of semiconductor objects of interest according to the method steps of any of the clauses 23 to 32.
Clause 38: The system according to any of the clauses 34 to 37, wherein the charged particle beam system is a dual beam system, including a focused ion beam system and a charged particle image system configured for obtaining a plurality of 2D cross section image slice by a slice- and image-method, and wherein the control unit is configured for performing the slice- and image-method by repeatedly milling and imaging a plurality of 2D cross section image slices through an inspection volume in wafer.
Clause 39: The system according to any of the clauses 34 to 38, further including a wafer table for receiving and holding a wafer, the wafer table including actuators and sensors configured for positioning and moving the wafer table.
Clause 40: A method according to any of the clauses 1 to 22, wherein the semiconductor object of interest is a HAR channel, and wherein the parametrized description includes a set of rings or circles.
Clause 41: A method of generating training data for training of a contiguous machine learning algorithm for providing quantitative measurement results of a parameter of a plurality of repetitive HAR channels from cross section images generated by a charged particle beam system, the method including:
   selecting a parametrized description including a set of circles or rings, and wherein the parametrized description is including at least on radius of a circle or ring as a parameter with a parameter value,
   generating a set of training cross section image segments of HAR channels, the training cross section image segments including a variation of the parameter value of the parametrized description, each parameter value is representing a measurement result of the parameter of an instance of a HAR channel cross section,
   wherein the variation of the parameter value is within a selected parameter value range.
Clause 42: The method according to clauses 41, further including any of the method steps 2 to 22.
Clause 43: A method of generating first training data for training of a machine learning algorithm for providing measurement results of a parameter of a semiconductor object of interest with a charged particle beam system, comprising:
   receiving CAD data of the semiconductor object of interest; and
   receiving imaging parameters of the charged particle beam system; and
   generating first training data by physical simulation of an imaging with the charged particle beam system based on the CAD data of the semiconductor object of interest and imaging parameters of the charged particle beam system.
Clause 44: The method of clause 43, further comprising selecting a parametrized description of the CAD data of the semiconductor object of interest, the parametrized description comprises the parameter.
Clause 45: The method according to clause 43, wherein the parameter of the parametrized description of the CAD data is a member selected from the group consisting of a length, a diameter, a distance, an area, an angle, a radius, an ellipticity, an aspect ratio, a curvature, a periodicity, a polygon parameter.
Clause 46: The method according to clause 44 or 45, wherein generating first training data comprises varying the parameter value of the CAD data according to a selected parameter value range of the parameter.
Clause 47: The method according to clause 46, wherein generating first training data further comprises annotating each training data with a parameter value.
Clause 48: The method according to any of the clause 43 to 47, wherein the imaging parameters comprise at least a member of the group consisting of a resolution, a contrast, and a noise level achieved by the charged particle beam system.
Clause 49: The method according to clause 48, wherein the imaging parameters of the charged particle beam system further comprise at least a member of the group consisting of a point spread function, a dwell time, a contrast method, a material contrast, and a topography contrast of the semiconductor object of interest.
Clause 50: The method according to any of the clause 43 to 49, comprising generating second training data by image processing of the first training data.
Clause 51: The method according to clause 50, wherein the image processing includes at least a member of the group consisting of a variation of a scale, a change of a shape, an interpolation, a morphologic operation, a pattern substitution, a noise addition, a particle defect addition.
Clause 52: A method of annotating training data for training of a machine learning algorithm for providing measurement results of a parameter of a semiconductor object of interest, comprising
   receiving a set of training cross section image segments of the semiconductor object of interest, the training cross section image segments comprising a variation of a parameter value of the semiconductor object of interest;
   selecting a parametrized description of the semiconductor object of interest, the parametrized description comprises the parameter;
   adjusting a parameter value of the parameter of the parametrized description to each detected instance of the semiconductor object of interest in the set of training cross section image segments;
   annotating each detected instance of the semiconductor object of interest in the set of training cross section image segments with the adjusted parameter value.
Clause 53: The method according to clause 52, wherein the parameter of the parametrized description of the semiconductor object of interest comprises a member of a group consisting of a length, a diameter, a distance, an area, an angle, a radius, an ellipticity, an aspect ratio, a curvature, a periodicity, and a polygon parameter.
Clause 54: The method according to clause 52 or 53, wherein selecting the parametrized description comprises presenting via a user interface a plurality of parametrized descriptions for selection and configuring of the selected parametrized description via a user input.
Clause 55: The method according to any of the clauses 52 to 54, further comprising automatically detecting, based on the selected parametrized description, instances of the semiconductor object of interest in the set of training cross section image segments.
Clause 56: The method according to any of the clauses 52 to 55, further comprising automatically adjusting a parameter value for each detected instance of the semiconductor object of interest by image processing.
Clause 57: The method according to any of the clauses 52 to 55, comprising applying a physical simulation model to the parametric description of the semiconductor object of interest with a parameter value and adjusting the parameter value by physically inspired forward optimization.
Clause 58: The method according to clause 57, wherein the physical simulation model comprises imaging parameters of a charged particle device comprise, the imaging parameters comprising at least a member of the group consisting of a resolution, a contrast, and a noise level, a point spread function, a dwell time, a contrast method, a material contrast, and a topography contrast.
Clause 59: The method according to any of the clauses 52 to 58, comprising graphically presenting via a user interface the parametrized description with the adjusted parameter value at at least one detected instance of the semiconductor object of interest.
Clause 60: The method according to clause 59, comprising receiving, via a user input, a confirmation or refinement of the parameter value at at least one detected instance of the semiconductor object of interest.
Clause 61: The method according to any of the clauses 52 to 60, wherein selecting the parametrized description is based on CAD information of the semiconductor object of interest.
Clause 62: A method of generating training data for a machine learning algorithm for image segmentation of cross section images of a semiconductor object of interest, comprising
   receiving a set of training cross section images of the semiconductor object of interest, the training cross section images comprising a variation of a parameter value of the semiconductor object of interest;
   selecting a parametrized description of the semiconductor object of interest;
   adjusting a parameter value of a parameter of the parametrized description to each detected instance of the semiconductor object of interest in the set of training cross section images;
   automatically annotating each image pixel with a pixel annotation value according to the adjusted parameter value of the parameter of the parametrized description.
Clause 63: The method according to clause 62, wherein the parameter of the parametrized description of the semiconductor object of interest comprises a member of a group consisting of a length, a diameter, a distance, an area, an angle, a radius, an ellipticity, an aspect ratio, a curvature, a periodicity, and a polygon parameter.
Clause 64: The method according to clause 62 or 63, wherein selecting the parametrized description comprises presenting via a user interface a plurality of parametrized descriptions for selection and configuring of the selected parametrized description via a user input.
Clause 65: The method according to any of the clauses 62 to 64, further comprising automatically detecting, based on the selected parametrized description, instances of the semiconductor object of interest in the set of training cross section images.
Clause 66: The method according to any of the clauses 62 to 65, further comprising automatically adjusting a parameter value for each detected instance of the semiconductor object of interest by image processing.
Clause 67: The method according to any of the clauses 62 to 65, comprising applying a physical simulation model to the parametric description of the semiconductor object of interest with a parameter value and adjusting the parameter value by physically inspired forward optimization.
Clause 68: The method according to clause 67, wherein the physical simulation model comprises imaging parameters of a charged particle device comprise, the imaging parameters comprising at least a member of the group consisting of a resolution, a contrast, and a noise level, a point spread function, a dwell time, a contrast method, a material contrast, and a topography contrast.
Clause 69: The method according to any of the clauses 62 to 68, comprising graphically presenting via a user interface the parametrized description with the adjusted parameter value at at least one detected instance of the semiconductor object of interest.
Clause 70: The method according to clause 69, comprising receiving, via a user input, a confirmation or refinement of the parameter value at at least one detected instance of the semiconductor object of interest.
Clause 71: The method according to any of the clauses 62 to 70, wherein selecting the parametrized description is based on CAD information of the semiconductor object of interest.

The disclosure described by examples and embodiments is however not limited to the clauses but can be implemented by those skilled in the art by various combinations or modifications.

### A LIST OF REFERENCE NUMBERS IS PROVIDED

1 Dual Beam system
2 Operation Control Unit
4 first cross section image features
6 measurement sites
8 wafer
15 wafer support table
16 stage control unit
17 Secondary Electron detector
19 Control Unit
40 charged particle beam (CPB) imaging system
42 Optical Axis of imaging system
43 Intersection point
44 Imaging charged particle beam
48 Fib Optical Axis
50 FIB column
51 focused ion beam
52 cross section surface
53 cross section surface
55 wafer top surface
155 wafer stage
160 inspection volume
201 processing engine
203 memory
205 User interface
219 memory
231 Interface unit
307 measured cross section image of HAR structure
311 cross section image slice
313 word lines
315 edge with surface
317 ring zone of HAR structure
319 initial parametric description
321 center position
323 amended parametric description
325 defect or deviation
327 pixelwise annotated rings
329 final parametric description
345 raster
363 average HAR channel trajectory
400 user interface display
401 user command devices
403 image display area
405 toolbar
407 selection box
409 graphical illustrations of parametric descriptions
411 list of annotation parameter values
413 list of parameter value ranges
414 histogram
421 graphical pointer
1000 system for performing measurement of semiconductor objects

1. A method of generating first training data for training a machine learning algorithm to provide measurement results of a parameter of a semiconductor object of interest with a charged particle beam system, the method comprising:
receiving CAD data of the semiconductor object of interest;
receiving imaging parameters of the charged particle beam system; and
generating first training data by physical simulation of an imaging with the charged particle beam system based on the CAD data of the semiconductor object of interest and imaging parameters of the charged particle beam system.

2. The method of claim 1, further comprising selecting a parametrized description of the CAD data of the semiconductor object of interest, wherein the parametrized description comprises the parameter.

3. The method of claim 2, wherein the parameter of the parametrized description of the CAD data comprises a member selected from the group consisting of a length, a diameter, a distance, an area, an angle, a radius, an ellipticity, an aspect ratio, a curvature, a periodicity, and a polygon parameter.

4. The method of claim 2, wherein generating the first training data comprises varying the parameter value of the CAD data according to a selected parameter value range of the parameter.

5. The method of claim 4, wherein generating the first training data further comprises annotating each training datum with a parameter value.

6. The method of claim 1, wherein the imaging parameters comprise a member selected from the group consisting of a resolution, a contrast, and a noise level achieved by the charged particle beam system.

7. The method of claim 6, wherein the imaging parameters of the charged particle beam system further comprise a member selected from the group consisting of a point spread function, a dwell time, a contrast method, a material contrast, and a topography contrast of the semiconductor object of interest.

8. The method of claim 1, further comprising generating second training data by image processing the first training data.

9. The method of claim 8, wherein the image processing the first training data comprises a member selected from the group consisting of varying a scale, changing a shape, interpolating, a morphologic operation, a pattern substitution, a noise addition, a particle defect addition.

10. One or more machine-readable hardware storage devices comprising instructions that are executable by one or more processing devices to perform operations comprising the method of claim 1.

11. A system, comprising:
one or more processing devices; and
one or more machine-readable hardware storage devices comprising instructions that are executable by the one or more processing devices to perform operations comprising the method of claim 1.

12. A method of annotating training data for training of a machine learning algorithm to provide measurement results of a parameter of a semiconductor object of interest, the method comprising:
receiving a set of training cross section image segments of the semiconductor object of interest, the training cross section image segments comprising a variation of a parameter value of the semiconductor object of interest;
selecting a parametrized description of the semiconductor object of interest, the parametrized description comprising the parameter;
adjusting a parameter value of the parameter of the parametrized description to each detected instance of the semiconductor object of interest in the set of training cross section image segments; and
annotating each detected instance of the semiconductor object of interest in the set of training cross section image segments with the adjusted parameter value.

13. The method of claim 12, wherein the parameter of the parametrized description of the semiconductor object of interest comprises a member selected from the group consisting of a length, a diameter, a distance, an area, an angle, a radius, an ellipticity, an aspect ratio, a curvature, a periodicity, and a polygon parameter.

14. The method of claim 12, wherein selecting the parametrized description comprises presenting via a user interface a plurality of parametrized descriptions for selection and configuring the selected parametrized description via a user input.

15. The method of claim 12, further comprising automatically detecting, based on the selected parametrized description, instances of the semiconductor object of interest in the set of training cross section image segments.

16. The method of claim 12, further comprising automatically adjusting a parameter value for each detected instance of the semiconductor object of interest by image processing.

17. The method of claim 12, further comprising applying a physical simulation model to the parametric description of the semiconductor object of interest with a parameter value, and adjusting the parameter value by physically inspired forward optimization.

18. The method of claim 17, wherein the physical simulation model comprises imaging parameters of a charged particle device comprise, and the imaging parameters comprise a member selected from the group consisting of a resolution, a contrast, a noise level, a point spread function, a dwell time, a contrast method, a material contrast, and a topography contrast.

19. The method of claim 12, further comprising graphically presenting via a user interface the parametrized description with the adjusted parameter value at at least one detected instance of the semiconductor object of interest.

20.-22. (canceled)

23. A system, comprising:
one or more processing devices; and
one or more machine-readable hardware storage devices comprising instructions that are executable by the one or more processing devices to perform operations comprising the method of claim 12.

24.-35. (canceled)
